(19) United States
(12) Patent Application Publication
(10) Pub. No.: US 2024/0421775 A1
(43) Pub. Date: Dec. 19, 2024

(54) DOHERTY AMPLIFICATION CIRCUIT

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/818,671

(22) Filed: Aug. 29, 2024

Related U.S. Application Data
(63) Continuation of application No. PCT/JP2023/006217, filed on Feb. 21, 2023.

(30) Foreign Application Priority Data
Apr. 22, 2022 (JP) 2022-071030

(51) Int. Cl. H03F 1/02; H03F 3/24

(52) U.S. Cl. CPC H03F 1/0288; H03F 3/245; H03F 2200/451

(57) ABSTRACT

A Doherty amplification circuit includes a carrier amplifier, a peak amplifier, a phase shift circuit, a phase shift circuit connected to an output end of the peak amplifier, a transformer including an input terminal connected to an output end of the carrier amplifier, and output terminals, and a transformer including input terminals, which are respectively connected to the output terminals of the transformer, and an output terminal connected to an antenna connection terminal, in which the phase shift circuit is connected between the output terminal of the transformer and the input terminal of the transformer, and the peak amplifier and the phase shift circuit are connected between the output terminal of the transformer and the input terminal of the transformer.

### CROSS-REFERENCE TO RELATED APPLICATIONS

This is a continuation application of PCT/JP2023/006217, filed on Feb. 21, 2023, designating the United States of America, which is based on and claims priority to Japanese Patent Application No. JP 2022-071030 filed on Apr. 22, 2022. The entire contents of the above-identified applications, including the specifications, drawings and claims, are incorporated herein by reference in their entirety.

### TECHNICAL FIELD

The present disclosure relates to a Doherty amplification circuit.

### BACKGROUND ART

Patent Document 1 discloses a Doherty amplification circuit including a first amplifier (carrier amplifier) that amplifies a first signal split from an input signal in a region in which a power level of the input signal is equal to or higher than a first level, to output a second signal, and a second amplifier (peak amplifier) that amplifies a third signal split from the input signal in a region in which the power level of the input signal is equal to or higher than a second level higher than the first level, to output a fourth signal.

### CITATION LIST

### Patent Document

Patent Document 1: Japanese Unexamined Patent Application Publication No. 2018-137566

### SUMMARY OF DISCLOSURE

### Technical Problem

However, in the related art described above, it is difficult to reduce circuit scales of the carrier amplifier and the peak amplifier.

Therefore, the present disclosure provides a Doherty amplification circuit that can realize high efficiency and reduction in a circuit scale.

### Solution to Problem

An aspect of the present disclosure provides a Doherty amplification circuit including: a first carrier amplifier; a first peak amplifier; a first phase shift circuit; a second phase shift circuit connected to an output end of the first peak amplifier; a first transformer including an input terminal connected to an output end of the first carrier amplifier, a first output terminal, and a second output terminal; and a second transformer including a first input terminal and a second input terminal, which are respectively connected to the first output terminal and the second output terminal of the first transformer, and an output terminal connected to a first antenna connection terminal, in which the first phase shift circuit is connected between the first output terminal of the first transformer and the first input terminal of the second transformer, and the first peak amplifier and the second phase shift circuit are connected between the second output terminal of the first transformer and the second input terminal of the second transformer.

An aspect of the present disclosure provides a Doherty amplification circuit including: a carrier amplifier; a first peak amplifier and a second peak amplifier; a first phase shift circuit and a second phase shift circuit; a third phase shift circuit connected to an output end of the second peak amplifier; a first transformer including an input terminal connected to an output end of the carrier amplifier, a first output terminal, and a second output terminal; a second transformer including an input terminal connected to the second output terminal of the first transformer, a first output terminal, and a second output terminal; and a third transformer including a first input terminal, a second input terminal, and a third input terminal, which are respectively connected to the first output terminal of the first transformer and the first output terminal and the second output terminal of the second transformer, and an output terminal connected to an antenna connection terminal, in which the first phase shift circuit is connected between the first output terminal of the first transformer and the first input terminal of the third transformer, the first peak amplifier is connected between the second output terminal of the first transformer and the input terminal of the second transformer, the second phase shift circuit is connected between the first output terminal of the second transformer and the second input terminal of the third transformer, and the second peak amplifier and the third phase shift circuit are connected between the second output terminal of the second transformer and the third input terminal of the third transformer.

An aspect of the present disclosure provides a Doherty amplification circuit including: a carrier amplifier configured to amplify an input signal; a first transformer configured to split the input signal amplified by the carrier amplifier into a first split signal and a second split signal; a first phase shift circuit configured to adjust a phase of the first split signal; a peak amplifier configured to amplify the second split signal; a second phase shift circuit configured to adjust a phase of the second split signal amplified by the peak amplifier; and a second transformer configured to combine the first split signal having the phase adjusted by the first phase shift circuit and the second split signal having the phase adjusted by the second phase shift circuit.

### Advantageous Effects of Disclosure

According to the present disclosure, it is possible to realize the high efficiency and the reduction in the circuit scale.

### BRIEF DESCRIPTION OF DRAWINGS

FIG. 1 is a circuit configuration diagram of a Doherty amplification circuit according to Embodiment 1.

FIG. 2 is a circuit configuration diagram of a Doherty amplification circuit according to Embodiment 2.

FIG. 3 is a diagram illustrating an example of a connection state and a signal flow of the Doherty amplification circuit according to Embodiment 2 in 4×4 multiple-input and multiple-output (MIMO).

FIG. 4A is a diagram illustrating a first example of a connection state and a signal flow of the Doherty amplification circuit according to Embodiment 2 in 2×2 MIMO.

FIG. 4B is a diagram illustrating a second example of the connection state and the signal flow of the Doherty amplification circuit according to Embodiment 2 in the 2×2 MIMO.

FIG. 5A is a diagram illustrating a first example of a connection state and a signal flow of the Doherty amplification circuit according to Embodiment 2 in single-input and single-output (SISO).

FIG. 5B is a diagram illustrating a second example of the connection state and the signal flow of the Doherty amplification circuit according to Embodiment 2 in the SISO.

FIG. 5C is a diagram illustrating a third example of the connection state and the signal flow of the Doherty amplification circuit according to Embodiment 2 in the SISO.

FIG. 6 is a circuit configuration diagram of a Doherty amplification circuit according to Embodiment 3.

FIG. 7 is a circuit configuration diagram of a Doherty amplification circuit according to Embodiment 4.

### DESCRIPTION OF EMBODIMENTS

### Background Leading to Present Disclosure

In a Doherty amplification circuit in the related art, a carrier amplifier and a peak amplifier are connected in parallel, and thus a circuit scale of an integrated circuit is increased in a case in which the carrier amplifier and the peak amplifier are implemented in the single integrated circuit. In particular, in a case in which the Doherty amplification circuit is used as a final stage of a multi-stage amplification circuit, the carrier amplifier and the peak amplifier are connected in parallel at an input stage, and thus the disposition of the carrier amplifier and the peak amplifier is restricted, leading to the increase in the circuit scale.

Therefore, hereinafter, a Doherty amplification circuit that can realize the reduction in the circuit scale while maintaining high efficiency will be described in detail based on embodiments. The embodiments described below are all inclusive or specific examples. Numerical values, shapes, materials, constituent elements, disposition and connection forms of constituent elements, and the like illustrated in the following embodiments are merely examples and are not intended to limit the present disclosure.

Each drawing is a schematic diagram in which appropriate emphasis, omission, or adjustment of a ratio is made for the purpose of illustrating the present disclosure, and is not necessarily strictly illustrated, and may be different from the actual shape, positional relationship, and ratio. In the respective drawings, substantially the same configurations are denoted by the same reference numerals, and the duplicate description may be omitted or simplified.

In a circuit configuration of the present disclosure, the expression “connected” means a case of being electrically connected via another circuit element, as well as a case of being directly connected by a connection terminal and/or a wiring conductor. The expression “connected between A and B” is understood to be a connection to both A and B between A and B, and includes series connection to a path connecting A and B, as well as parallel connection (shunt connection) between the path and a ground.

In the present disclosure, the term “terminal” is understood to be an end point of a conductor in elements. In a case in which an impedance of the path between the elements is sufficiently low, the terminal is interpreted as not only a single point but also any point on the path between the elements or the entire path.

In the present disclosure, the Doherty amplification circuit is understood to be an amplification circuit that realizes the high efficiency by using a plurality of amplifiers as the carrier amplifier and the peak amplifier. The carrier amplifier is understood to be an amplifier that operates even regardless of whether the power of a high frequency signal (input) is low or high in the Doherty amplification circuit. The peak amplifier may be understood to be an amplifier that mainly operates in a case in which the power of the high frequency signal (input) is high in the Doherty amplification circuit. Therefore, the high frequency signal is mainly amplified by the carrier amplifier in a case in which the input power of the high frequency signal is low, and the high frequency signals are amplified by the carrier amplifier and the peak amplifier and combined in a case in which the input power of the high frequency signal is high. With such an operation, in the Doherty amplification circuit, a load impedance assuming seen from the carrier amplifier is increased at the low output power, and the efficiency at the low output power is improved.

### Embodiment 1

Hereinafter, Embodiment 1 will be described.

### 1.1 Circuit Configuration of Communication Device 5

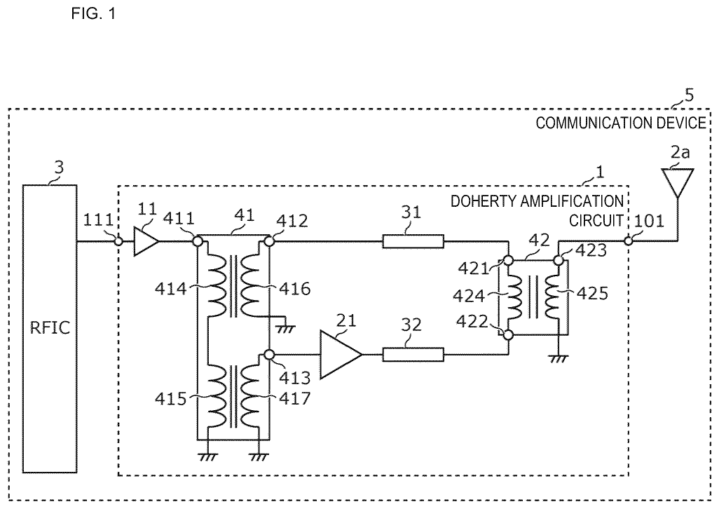

First, a circuit configuration of a communication device 5 according to the present embodiment will be described with reference to FIG. 1. FIG. 1 is a circuit configuration diagram of the communication device 5 according to the present embodiment.

The communication device 5 corresponds to a UE in a cellular communication system and is typically a cellular phone, a smartphone, a tablet computer, or a wearable device, for example. The communication device 5 may be an internet-of-things (IoT) sensor device, a medical/healthcare device, a car, an unmanned aerial vehicle (UAV) (so-called drone), or an automated guided vehicle (AGV). In addition, the communication device 5 may be used as a BS in the cellular communication system.

As illustrated in FIG. 1, the communication device 5 includes a Doherty amplification circuit 1, an antenna 2a, and a radio frequency integrated circuit (RFIC) 3.

The Doherty amplification circuit 1 transmits a high frequency signal between the antenna 2a and the RFIC 3. An internal configuration of the Doherty amplification circuit 1 will be described below.

The antenna 2a is connected to an antenna connection terminal 101 of the Doherty amplification circuit 1. The antenna 2a transmits the high frequency signal output from the Doherty amplification circuit 1.

The RFIC 3 is an example of a signal processing circuit that processes the high frequency signal. Specifically, the RFIC 3 performs signal processing such as up-conversion on a transmission signal input from a baseband integrated circuit (BBIC) or the like, and outputs a high frequency transmission signal generated by this signal processing to the Doherty amplification circuit 1. The RFIC 3 includes a control unit that controls the Doherty amplification circuit 1. A part or all of functions of the control unit of the RFIC 3 may be implemented outside the RFIC 3, and may be implemented in, for example, the BBIC or the Doherty amplification circuit 1.

In the communication device 5 according to the present embodiment, the antenna 2a is an optional constituent element.

### 1.2 Circuit Configuration of Doherty Amplification Circuit 1

Next, a circuit configuration of the Doherty amplification circuit 1 included in the communication device 5 will be described with reference to FIG. 1. As illustrated in FIG. 1, the Doherty amplification circuit 1 includes a carrier amplifier 11, a peak amplifier 21, phase shift circuits 31 and 32, transformers 41 and 42, an antenna connection terminal 101, and a high frequency input terminal 111. Hereinafter, the constituent elements of the Doherty amplification circuit 1 will be described in order.

The antenna connection terminal 101 is an example of a first antenna connection terminal. The antenna connection terminal 101 is connected to the transformer 42 inside the Doherty amplification circuit 1, and is connected to the antenna 2a outside the Doherty amplification circuit 1. The transmission signal amplified by the Doherty amplification circuit 1 is supplied to the antenna 2a through the antenna connection terminal 101.

The high frequency input terminal 111 is a terminal for receiving the high frequency signal from outside the Doherty amplification circuit 1. The high frequency input terminal 111 is connected to the RFIC 3 outside the Doherty amplification circuit 1, and is connected to the carrier amplifier 11 inside the Doherty amplification circuit 1.

The carrier amplifier 11 is an example of a first carrier amplifier, and is connected between the high frequency input terminal 111 and the transformer 41. Specifically, an input end of the carrier amplifier 11 is connected to the high frequency input terminal 111, and an output end of the carrier amplifier 11 is connected to an input terminal 411 of the transformer 41. The carrier amplifier 11 can operate, for example, in a class-A or a class-AB to amplify the input signal received through the high frequency input terminal 111.

The peak amplifier 21 is an example of a first peak amplifier, and is connected between the transformers 41 and 42. Specifically, an input end of the peak amplifier 21 is connected to an output terminal 413 of the transformer 41, and an output end of the peak amplifier 21 is connected to an input terminal 422 of the transformer 42 with the phase shift circuit 32 interposed therebetween. The peak amplifier 21 can operate, for example, in a class-C to amplify a part of the signal amplified by the carrier amplifier 11.

The phase shift circuit 31 is an example of a first phase shift circuit, and is connected between the transformers 41 and 42. Specifically, one end of the phase shift circuit 31 is connected to an output terminal 412 of the transformer 41, and the other end of the phase shift circuit 31 is connected to an input terminal 421 of the transformer 42.

The phase shift circuit 32 is an example of a second phase shift circuit, and is connected between the transformers 41 and 42. Specifically, one end of the phase shift circuit 32 is connected to the output end of the peak amplifier 21, and the other end of the phase shift circuit 32 is connected to the input terminal 422 of the transformer 42. That is, the peak amplifier 21 and the phase shift circuit 32 are connected between the output terminal 413 of the transformer 41 and the input terminal 422 of the transformer 42.

Each of the phase shift circuits 31 and 32 can adjust a phase of the input signal. Specifically, each of the phase shift circuits 31 and 32 can shift the phase of the input signal by −90 degrees (delay the phase of the input signal by −90 degrees). As the phase shift circuits 31 and 32, for example, a quarter wavelength transmission line can be used. The phase shift circuits 31 and 32 may include an inductor and/or a capacitor. As a result, in the phase shift circuits 31 and 32, a line length can be shortened. A phase adjustment amount in each of the phase shift circuits 31 and 32 is not limited to −90 degrees.

The transformer 41 is an example of a first transformer, and includes the input terminal 411 and the output terminals 412 and 413. The input terminal 411 is connected to the output end of the carrier amplifier 11. The output terminal 412 is an example of a first output terminal, and is connected to the input terminal 421 of the transformer 42 with the phase shift circuit 31 interposed therebetween. The output terminal 413 is an example of a second output terminal, and is connected to the input end of the peak amplifier 21.

Specifically, as illustrated in FIG. 1, the transformer 41 includes input side coils 414 and 415 and output side coils 416 and 417.

The input side coil 414 is an example of a first input side coil, and has the input terminal 411 at one end. That is, one end of the input side coil 414 is the input terminal 411, and is connected to the output end of the carrier amplifier 11. On the other hand, the other end of the input side coil 414 is connected to one end of the input side coil 415.

The input side coil 415 is an example of a second input side coil. One end of the input side coil 415 is connected to the other end of the input side coil 414. The other end of the input side coil 415 is connected to the ground.

The output side coil 416 is an example of a first output side coil, and is configured to couple with the input side coil 414. The output side coil 416 has the output terminal 412 at one end. That is, one end of the output side coil 416 is the output terminal 412, and is connected to one end of the phase shift circuit 31. On the other hand, the other end of the output side coil 416 is connected to the ground.

The output side coil 417 is an example of a second output side coil, and is configured to couple with the input side coil 415. The output side coil 417 has the output terminal 413 at one end. That is, one end of the output side coil 417 is the output terminal 413, and is connected to the input end of the peak amplifier 21. On the other hand, the other end of the output side coil 417 is connected to the ground.

With such a configuration, the transformer 41 can split the input signal amplified by the carrier amplifier 11 into two split signals (first split signal and second split signal). In this case, the power of the signal from the output terminal 412 is higher than the power of the signal from the output terminal 413. A power ratio (that is, a split ratio) of the two split signals is not limited to this. For example, the power ratio between the two split signals may be 1:1.

The configuration of the transformer 41 is not limited to the configuration illustrated in FIG. 1. For example, the transformer 41 may include a pair of the input side coil and the output side coil. In this case, the input terminal 411 may be formed at one end of the input side coil, and the output terminals 412 and 413 may be respectively formed at both ends of the output side coil.

The transformer 42 is an example of a second transformer, and includes the input terminals 421 and 422 and an output terminal 423. The input terminal 421 is an example of a first input terminal, and is connected to the output terminal 412 of the transformer 41 with the phase shift circuit 31 interposed therebetween. The input terminal 422 is an example of a second input terminal, and is connected to the output end of the peak amplifier 21 with the phase shift circuit 32 interposed therebetween. The output terminal 423 is connected to the antenna connection terminal 101.

Specifically, as illustrated in FIG. 1, the transformer 42 includes an input side coil 424 and an output side coil 425.

The input side coil 424 has the input terminals 421 and 422 at both ends. That is, one end of the input side coil 424 is the input terminal 421, and is connected to the other end of the phase shift circuit 31. On the other hand, the other end of the input side coil 424 is the input terminal 422, and is connected to the other end of the phase shift circuit 32.

The output side coil 425 is configured to couple with the input side coil 424. The output side coil 425 has the output terminal 423 at one end. That is, one end of the output side coil 425 is the output terminal 423, and is connected to the antenna connection terminal 101. On the other hand, the other end of the output side coil 425 is connected to the ground.

With such a configuration, the transformer 42 can combine the two input signals (output signals of the phase shift circuits 31 and 32). The configuration of the transformer 42 is not limited to the configuration illustrated in FIG. 1. For example, the transformer 42 may include two pairs of the input side coil and the output side coil, similar to the transformer 41.

The Doherty amplification circuit 1 illustrated in FIG. 1 is merely an example, and the configuration of the Doherty amplification circuit 1 is not limited to this. For example, the Doherty amplification circuit 1 may include a band pass filter between the output terminal 423 of the transformer 42 and the antenna connection terminal 101. In addition, for example, the Doherty amplification circuit 1 may include a reception path that is connected to the antenna connection terminal 101. In this case, the reception path may include the band pass filter, a low noise amplifier, and the like.

### 1.3 Effects, Etc

As described above, the Doherty amplification circuit 1 according to the present embodiment includes the carrier amplifier 11, the peak amplifier 21, the phase shift circuit 31, the phase shift circuit 32 connected to the output end of the peak amplifier 21, the transformer 41 including the input terminal 411 connected to the output end of the carrier amplifier 11, and the output terminals 412 and 413, the transformer 42 including the input terminals 421 and 422, which are respectively connected to the output terminals 412 and 413 of the transformer 41, and the output terminal 423 connected to the antenna connection terminal 101, in which the phase shift circuit 31 is connected between the output terminal 412 of the transformer 41 and the input terminal 421 of the transformer 42, and the peak amplifier 21 and the phase shift circuit 32 are connected between the output terminal 413 of the transformer 41 and the input terminal 422 of the transformer 42.

According to this, the output end of the carrier amplifier 11 is coupled with the input end of the peak amplifier 21 by the transformer 41. Therefore, since the carrier amplifier 11 and the peak amplifier 21 are not connected in parallel, it is not necessary to dispose the carrier amplifier 11 and the peak amplifier 21 side by side in the integrated circuit, and thus the degree of freedom in disposition can be increased. Further, the carrier amplifier 11 can be used in a stage preceding the peak amplifier 21, and thus the circuit scale can be reduced as compared to a configuration in which another amplifier is used in a stage preceding the carrier amplifier 11 and the peak amplifier 21 that are connected in parallel. Further, a Doherty operation can be realized, so that higher efficiency can be realized as compared to a multi-stage amplification circuit in the related art.

In addition, for example, in the Doherty amplification circuit 1 according to the present embodiment, the transformer 41 may include the input side coil 414 having the input terminal 411 of the transformer 41 at one end, the input side coil 415 having one end connected to the other end of the input side coil 414 of the transformer 41, the output side coil 416 having the output terminal 412 of the transformer 41 at one end and configured to couple with the input side coil 414 of the transformer 41, and the output side coil 417 having the output terminal 413 of the transformer 41 at one end and configured to couple with the input side coil 415 of the transformer 41, and the transformer 42 may include the input side coil 424 having the input terminal 421 and the input terminal 422 of the transformer 42 at both ends, and the output side coil 425 having the output terminal 423 of the transformer 42 at one end and configured to couple with the input side coil 424 of the transformer 42.

According to this, the first split signal and the second split signal that have the same phase are output from the output terminals 412 and 413 of the transformer 41. The phase of the second split signal is inverted by the peak amplifier 21, and is shifted by −90 degrees by the phase shift circuit 32. In the input of the transformer 42, since a phase difference of 180 degrees is preferred between the first split signal and the second split signal, a phase shift amount of the first split signal preferred for the phase shift circuit 31 is limited to −90 degrees. Therefore, a wiring length of the phase shift circuit 31 can be relatively shortened, and an overall circuit scale of the Doherty amplification circuit 1 can be reduced.

Further, the Doherty amplification circuit 1 according to the present embodiment includes the carrier amplifier 11 configured to amplify the input signal, the transformer 41 configured to split the input signal amplified by the carrier amplifier 11 into the first split signal and the second split signal, the phase shift circuit 31 configured to adjust the phase of the first split signal, the peak amplifier 21 configured to amplify the second split signal, the phase shift circuit 32 configured to adjust the phase of the second split signal amplified by the peak amplifier 21, and the transformer 42 configured to combine the first split signal having the phase adjusted by the phase shift circuit 31 and the second split signal having the phase adjusted by the phase shift circuit 32.

According to this, a part (second split signal) of the input signal amplified by the carrier amplifier 11 is amplified by the peak amplifier 21. Therefore, the carrier amplifier 11 and the peak amplifier 21 can be connected in series, and it is not necessary to dispose the carrier amplifier 11 and the peak amplifier 21 side by side in the integrated circuit, so that the degree of freedom in disposition can be increased. Further, the carrier amplifier 11 can be used in a stage preceding the peak amplifier 21, and thus the circuit scale can be reduced as compared to a configuration in which another amplifier is used in a stage preceding the carrier amplifier 11 and the peak amplifier 21 that are connected in parallel. Further, a Doherty operation can be realized, so that higher efficiency can be realized as compared to a multi-stage amplification circuit in the related art.

### Embodiment 2

Hereinafter, Embodiment 2 will be described. A communication device and a Doherty amplification circuit according to the present embodiment are mainly different from the communication device and the Doherty amplification circuit according to Embodiment 1 in that the communication device and the Doherty amplification circuit according to the present embodiment are configured to be usable in MIMO. Hereinafter, the communication device and the Doherty amplification circuit according to the present embodiment will be described with reference to the accompanying drawings, focusing on the difference from Embodiment 1.

### 2.1 Circuit Configuration of Communication Device 5A

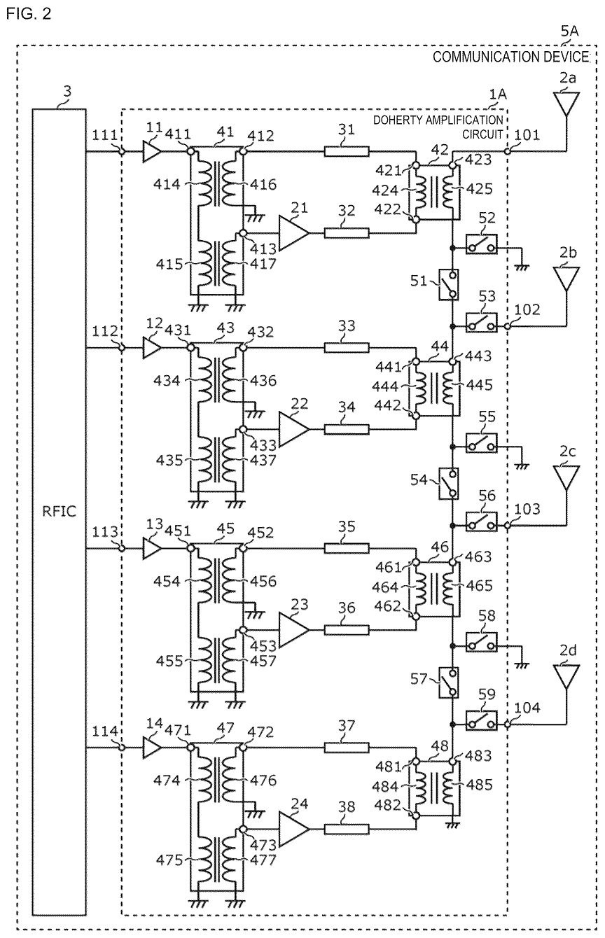

First, a circuit configuration of a communication device 5A according to the present embodiment will be described with reference to FIG. 2. FIG. 2 is a circuit configuration diagram of the communication device 5A according to the present embodiment.

The communication device 5A includes a Doherty amplification circuit 1A instead of the Doherty amplification circuit 1, and includes antennas 2b to 2d in addition to the antenna 2a.

The Doherty amplification circuit 1A transmits a high frequency signal between the antennas 2a to 2d and the RFIC 3. An internal configuration of the Doherty amplification circuit 1A will be described below.

The antennas 2a to 2d are respectively connected to antenna connection terminals 101 to 104 of the Doherty amplification circuit 1A. Each of the antennas 2a to 2d transmits the high frequency signal output from the Doherty amplification circuit 1A.

The antennas 2a to 2d are optional constituent elements in the communication device 5A according to the present embodiment.

### 2.2 Circuit Configuration of Doherty Amplification Circuit 1A

Next, a circuit configuration of the Doherty amplification circuit 1A included in the communication device 5A will be described with reference to FIG. 2. As illustrated in FIG. 2, the Doherty amplification circuit 1A includes carrier amplifiers 11 to 14, peak amplifiers 21 to 24, phase shift circuits 31 to 38, transformers 41 to 48, switches 51 to 59, the antenna connection terminals 101 to 104, and high frequency input terminals 111 to 114. Hereinafter, the constituent elements of the Doherty amplification circuit 1A will be described in order.

The antenna connection terminal 101 is an example of a first antenna connection terminal. The antenna connection terminal 101 is connected to the transformer 42 inside the Doherty amplification circuit 1A, and is connected to the antenna 2a outside the Doherty amplification circuit 1A.

The antenna connection terminal 102 is an example of a second antenna connection terminal. The antenna connection terminal 102 is connected to the transformer 44 with the switch 53 interposed therebetween inside the Doherty amplification circuit 1A, and is connected to the antenna 2b outside the Doherty amplification circuit 1A.

The antenna connection terminal 103 is an example of a third antenna connection terminal. The antenna connection terminal 103 is connected to the transformer 46 with the switch 56 interposed therebetween inside the Doherty amplification circuit 1A, and is connected to the antenna 2c outside the Doherty amplification circuit 1A.

The antenna connection terminal 104 is an example of a fourth antenna connection terminal. The antenna connection terminal 104 is connected to the transformer 48 with the switch 59 interposed therebetween inside the Doherty amplification circuit 1A, and is connected to the antenna 2d outside the Doherty amplification circuit 1A.

The high frequency input terminal 111 is a terminal for receiving the high frequency signal from outside the Doherty amplification circuit 1A. The high frequency input terminal 111 is connected to the RFIC 3 outside the Doherty amplification circuit 1A, and is connected to the carrier amplifier 11 inside the Doherty amplification circuit 1A.

The high frequency input terminal 112 is a terminal for receiving the high frequency signal from outside the Doherty amplification circuit 1A. The high frequency input terminal 112 is connected to the RFIC 3 outside the Doherty amplification circuit 1A, and is connected to the carrier amplifier 12 inside the Doherty amplification circuit 1A.

The high frequency input terminal 113 is a terminal for receiving the high frequency signal from outside the Doherty amplification circuit 1A. The high frequency input terminal 113 is connected to the RFIC 3 outside the Doherty amplification circuit 1A, and is connected to the carrier amplifier 13 inside the Doherty amplification circuit 1A.

The high frequency input terminal 114 is a terminal for receiving the high frequency signal from outside the Doherty amplification circuit 1A. The high frequency input terminal 114 is connected to the RFIC 3 outside the Doherty amplification circuit 1A, and is connected to the carrier amplifier 14 inside the Doherty amplification circuit 1A.

The carrier amplifier 11 is an example of a first carrier amplifier, and is connected between the high frequency input terminal 111 and the transformer 41. Specifically, an input end of the carrier amplifier 11 is connected to the high frequency input terminal 111, and an output end of the carrier amplifier 11 is connected to an input terminal 411 of the transformer 41. The carrier amplifier 11 can operate, for example, in a class-A or a class-AB to amplify the input signal received through the high frequency input terminal 111.

The carrier amplifier 12 is an example of a second carrier amplifier, and is connected between the high frequency input terminal 112 and the transformer 43. Specifically, an input end of the carrier amplifier 12 is connected to the high frequency input terminal 112, and an output end of the carrier amplifier 12 is connected to an input terminal 431 of the transformer 43. The carrier amplifier 12 can operate, for example, in a class-A or a class-AB to amplify the input signal received through the high frequency input terminal 112.

The carrier amplifier 13 is an example of a third carrier amplifier, and is connected between the high frequency input terminal 113 and the transformer 45. Specifically, the input end of the carrier amplifier 13 is connected to the high frequency input terminal 113, and the output end of the carrier amplifier 13 is connected to the input terminal 451 of the transformer 45. The carrier amplifier 13 can operate, for example, in a class-A or a class-AB to amplify the input signal received through the high frequency input terminal 113.

The carrier amplifier 14 is an example of a fourth carrier amplifier, and is connected between the high frequency input terminal 114 and the transformer 47. Specifically, an input end of the carrier amplifier 14 is connected to the high frequency input terminal 114, and an output end of the carrier amplifier 14 is connected to an input terminal 471 of the transformer 47. The carrier amplifier 14 can operate, for example, in a class-A or a class-AB to amplify the input signal received through the high frequency input terminal 114.

The peak amplifier 21 is an example of a first peak amplifier, and is connected between the transformers 41 and 42. Specifically, an input end of the peak amplifier 21 is connected to an output terminal 413 of the transformer 41, and an output end of the peak amplifier 21 is connected to an input terminal 422 of the transformer 42 with the phase shift circuit 32 interposed therebetween. The peak amplifier 21 can operate, for example, in a class-C to amplify a part of the signal amplified by the carrier amplifier 11.

The peak amplifier 22 is an example of a second peak amplifier, and is connected between the transformers 43 and 44. Specifically, the input end of the peak amplifier 22 is connected to the output terminal 433 of the transformer 43, and the output end of the peak amplifier 22 is connected to the input terminal 442 of the transformer 44 with the phase shift circuit 34 interposed therebetween. The peak amplifier 22 can operate, for example, in a class-C to amplify a part of the signal amplified by the carrier amplifier 12.

The peak amplifier 23 is an example of a third peak amplifier, and is connected between the transformers 45 and 46. Specifically, an input end of the peak amplifier 23 is connected to an output terminal 453 of the transformer 45, and an output end of the peak amplifier 23 is connected to an input terminal 462 of the transformer 46 with the phase shift circuit 36 interposed therebetween. The peak amplifier 23 can operate, for example, in a class-C to amplify a part of the signal amplified by the carrier amplifier 13.

The peak amplifier 24 is an example of a fourth peak amplifier, and is connected between the transformers 47 and 48. Specifically, an input end of the peak amplifier 24 is connected to an output terminal 473 of the transformer 47, and an output end of the peak amplifier 24 is connected to an input terminal 482 of the transformer 48 with the phase shift circuit 38 interposed therebetween. The peak amplifier 24 can operate, for example, in a class-C to amplify a part of the signal amplified by the carrier amplifier 14.

The phase shift circuit 31 is an example of a first phase shift circuit, and is connected between the transformers 41 and 42. Specifically, one end of the phase shift circuit 31 is connected to an output terminal 412 of the transformer 41, and the other end of the phase shift circuit 31 is connected to an input terminal 421 of the transformer 42.

The phase shift circuit 32 is an example of a second phase shift circuit, and is connected between the transformers 41 and 42. Specifically, one end of the phase shift circuit 32 is connected to the output end of the peak amplifier 21, and the other end of the phase shift circuit 32 is connected to the input terminal 422 of the transformer 42. That is, the peak amplifier 21 and the phase shift circuit 32 are connected between the output terminal 413 of the transformer 41 and the input terminal 422 of the transformer 42.

The phase shift circuit 33 is an example of a third phase shift circuit, and is connected between the transformers 43 and 44. Specifically, one end of the phase shift circuit 33 is connected to an output terminal 432 of the transformer 43, and the other end of the phase shift circuit 33 is connected to an input terminal 441 of the transformer 44.

The phase shift circuit 34 is an example of a fourth phase shift circuit, and is connected between the transformers 43 and 44. Specifically, one end of the phase shift circuit 34 is connected to the output end of the peak amplifier 22, and the other end of the phase shift circuit 34 is connected to the input terminal 442 of the transformer 44. That is, the peak amplifier 22 and the phase shift circuit 34 are connected between the output terminal 433 of the transformer 43 and the input terminal 442 of the transformer 44.

The phase shift circuit 35 is an example of a fifth phase shift circuit, and is connected between the transformers 45 and 46. Specifically, one end of the phase shift circuit 35 is connected to an output terminal 452 of the transformer 45, and the other end of the phase shift circuit 35 is connected to an input terminal 461 of the transformer 46.

The phase shift circuit 36 is an example of a sixth phase shift circuit, and is connected between the transformers 45 and 46. Specifically, one end of the phase shift circuit 36 is connected to the output end of the peak amplifier 23, and the other end of the phase shift circuit 36 is connected to the input terminal 462 of the transformer 46. That is, the peak amplifier 23 and the phase shift circuit 36 are connected between the output terminal 453 of the transformer 45 and the input terminal 462 of the transformer 46.

The phase shift circuit 37 is an example of a seventh phase shift circuit, and is connected between the transformers 47 and 48. Specifically, one end of the phase shift circuit 37 is connected to an output terminal 472 of the transformer 47, and the other end of the phase shift circuit 37 is connected to an input terminal 481 of the transformer 48.

The phase shift circuit 38 is an example of an eighth phase shift circuit, and is connected between the transformers 47 and 48. Specifically, one end of the phase shift circuit 38 is connected to the output end of the peak amplifier 24, and the other end of the phase shift circuit 38 is connected to the input terminal 482 of the transformer 48. That is, the peak amplifier 24 and the phase shift circuit 38 are connected between the output terminal 473 of the transformer 47 and the input terminal 482 of the transformer 48.

Each of the phase shift circuits 31 to 38 can adjust a phase of the input signal. Specifically, each of the phase shift circuits 31 to 38 can shift the phase of the input signal by −90 degrees (delay the phase of the input signal by −90 degrees). As the phase shift circuits 31 to 38, for example, a quarter wavelength transmission line can be used. The phase shift circuits 31 to 38 may include an inductor and/or a capacitor. As a result, in the phase shift circuits 31 to 38, a line length can be shortened. A phase adjustment amount in each of the phase shift circuits 31 to 38 is not limited to −90 degrees.

The transformer 41 is an example of a first transformer, and includes the input terminal 411 and the output terminals 412 and 413. The input terminal 411 is connected to the output end of the carrier amplifier 11. The output terminal 412 is an example of a first output terminal, and is connected to the input terminal 421 of the transformer 42 with the phase shift circuit 31 interposed therebetween. The output terminal 413 is an example of a second output terminal, and is connected to the input end of the peak amplifier 21.

Specifically, as illustrated in FIG. 2, the transformer 41 includes input side coils 414 and 415 and output side coils 416 and 417.

The input side coil 414 is an example of a first input side coil, and has the input terminal 411 at one end. That is, one end of the input side coil 414 is the input terminal 411, and is connected to the output end of the carrier amplifier 11. On the other hand, the other end of the input side coil 414 is connected to one end of the input side coil 415.

The input side coil 415 is an example of a second input side coil. One end of the input side coil 415 is connected to the other end of the input side coil 414. The other end of the input side coil 415 is connected to the ground.

The output side coil 416 is an example of a first output side coil, and is configured to couple with the input side coil 414. The output side coil 416 has the output terminal 412 at one end. That is, one end of the output side coil 416 is the output terminal 412, and is connected to one end of the phase shift circuit 31. On the other hand, the other end of the output side coil 416 is connected to the ground.

The output side coil 417 is an example of a second output side coil, and is configured to couple with the input side coil 415. The output side coil 417 has the output terminal 413 at one end. That is, one end of the output side coil 417 is the output terminal 413, and is connected to the input end of the peak amplifier 21. On the other hand, the other end of the output side coil 417 is connected to the ground.

With such a configuration, the transformer 41 can split the input signal amplified by the carrier amplifier 11 into two split signals (first split signal and second split signal). The configuration of the transformer 41 is not limited to the configuration illustrated in FIG. 2. For example, the transformer 41 may include a pair of the input side coil and the output side coil. In this case, the input terminal 411 may be formed at one end of the input side coil, and the output terminals 412 and 413 may be respectively formed at both ends of the output side coil.

The transformer 42 is an example of a second transformer, and includes the input terminals 421 and 422 and an output terminal 423. The input terminal 421 is an example of a first input terminal, and is connected to the output terminal 412 of the transformer 41 with the phase shift circuit 31 interposed therebetween. The input terminal 422 is an example of a second input terminal, and is connected to the output end of the peak amplifier 21 with the phase shift circuit 32 interposed therebetween. The output terminal 423 is connected to the antenna connection terminal 101.

Specifically, as illustrated in FIG. 2, the transformer 42 includes an input side coil 424 and an output side coil 425.

The input side coil 424 has the input terminals 421 and 422 at both ends. That is, one end of the input side coil 424 is the input terminal 421, and is connected to the other end of the phase shift circuit 31. On the other hand, the other end of the input side coil 424 is the input terminal 422, and is connected to the other end of the phase shift circuit 32.

The output side coil 425 is configured to couple with the input side coil 424. The output side coil 425 has the output terminal 423 at one end. That is, one end of the output side coil 425 is the output terminal 423, and is connected to the antenna connection terminal 101. On the other hand, the other end of the output side coil 425 is connected to the switches 51 and 52.

With such a configuration, the transformer 42 can combine the two input signals (output signals of the phase shift circuits 31 and 32). The configuration of the transformer 42 is not limited to the configuration illustrated in FIG. 2. For example, the transformer 42 may include two pairs of the input side coil and the output side coil, similar to the transformer 41.

The transformer 43 is an example of a third transformer, and includes the input terminal 431 and the output terminals 432 and 433. The input terminal 431 is connected to the output end of the carrier amplifier 12. Output terminal 432 is an example of a first output terminal, and is connected to the input terminal 441 of the transformer 44 with the phase shift circuit 33 interposed therebetween. The output terminal 433 is an example of a second output terminal, and is connected to the input end of the peak amplifier 22.

Specifically, as illustrated in FIG. 2, the transformer 43 includes input side coils 434 and 435 and output side coils 436 and 437.

The input side coil 434 is an example of a first input side coil, and has the input terminal 431 at one end. That is, one end of the input side coil 434 is the input terminal 431, and is connected to the output end of the carrier amplifier 12. On the other hand, the other end of the input side coil 434 is connected to one end of the input side coil 435.

The input side coil 435 is an example of a second input side coil. One end of the input side coil 435 is connected to the other end of the input side coil 434. The other end of the input side coil 435 is connected to the ground.

The output side coil 436 is an example of a first output side coil, and is configured to couple with the input side coil 434. The output side coil 436 has the output terminal 432 at one end. That is, one end of the output side coil 436 is the output terminal 432, and is connected to one end of the phase shift circuit 33. On the other hand, the other end of the output side coil 436 is connected to the ground.

The output side coil 437 is an example of a second output side coil, and is configured to couple with the input side coil 435. The output side coil 437 has the output terminal 433 at one end. That is, one end of the output side coil 437 is the output terminal 433, and is connected to the input end of the peak amplifier 22. On the other hand, the other end of the output side coil 437 is connected to the ground.

With such a configuration, the transformer 43 can split the input signal amplified by the carrier amplifier 12 into two split signals (first split signal and second split signal). The configuration of the transformer 43 is not limited to the configuration illustrated in FIG. 2. For example, the transformer 43 may include a pair of the input side coil and the output side coil. In this case, the input terminal 431 may be formed at one end of the input side coil, and the output terminals 432 and 433 may be respectively formed at both ends of the output side coil.

The transformer 44 is an example of a fourth transformer, and includes the input terminals 441 and 442 and an output terminal 443. The input terminal 441 is an example of a first input terminal, and is connected to the output terminal 432 of the transformer 43 with the phase shift circuit 33 interposed therebetween. The input terminal 442 is an example of a second input terminal, and is connected to the output end of the peak amplifier 22 with the phase shift circuit 34 interposed therebetween. The output terminal 443 is connected to the switches 51 and 53.

Specifically, as illustrated in FIG. 2, the transformer 44 includes an input side coil 444 and an output side coil 445.

The input side coil 444 has the input terminals 441 and 442 at both ends. That is, one end of the input side coil 444 is the input terminal 441, and is connected to the other end of the phase shift circuit 33. On the other hand, the other end of the input side coil 444 is the input terminal 442, and is connected to the other end of the phase shift circuit 34.

The output side coil 445 is configured to couple with the input side coil 444. The output side coil 445 has the output terminal 443 at one end. That is, one end of the output side coil 445 is the output terminal 443, and is connected to the switches 51 and 53. On the other hand, the other end of the output side coil 445 is connected to the switches 54 and 55.

With such a configuration, the transformer 44 can combine the two input signals (output signals of the phase shift circuits 33 and 34). The configuration of the transformer 44 is not limited to the configuration illustrated in FIG. 2. For example, the transformer 44 may include two pairs of the input side coil and the output side coil, similar to the transformer 43.

The transformer 45 is an example of a fifth transformer, and includes the input terminal 451 and the output terminals 452 and 453. The input terminal 451 is connected to the output end of the carrier amplifier 13. The output terminal 452 is an example of a first output terminal, and is connected to the input terminal 461 of the transformer 46 with the phase shift circuit 35 interposed therebetween. The output terminal 453 is an example of a second output terminal, and is connected to the input end of the peak amplifier 23.

Specifically, as illustrated in FIG. 2, the transformer 45 includes input side coils 454 and 455 and output side coils 456 and 457.

The input side coil 454 is an example of a first input side coil, and has the input terminal 451 at one end. That is, one end of the input side coil 454 is the input terminal 451, and is connected to the output end of the carrier amplifier 13. On the other hand, the other end of the input side coil 454 is connected to one end of the input side coil 455.

The input side coil 455 is an example of a second input side coil. One end of the input side coil 455 is connected to the other end of the input side coil 454. The other end of the input side coil 455 is connected to the ground.

The output side coil 456 is an example of a first output side coil, and is configured to couple with the input side coil 454. The output side coil 456 has the output terminal 452 at one end. That is, one end of the output side coil 456 is the output terminal 452, and is connected to one end of the phase shift circuit 35. On the other hand, the other end of the output side coil 456 is connected to the ground.

The output side coil 457 is an example of a second output side coil, and is configured to couple with the input side coil 455. The output side coil 457 has the output terminal 453 at one end. That is, one end of the output side coil 457 is the output terminal 453, and is connected to the input end of the peak amplifier 23. On the other hand, the other end of the output side coil 457 is connected to the ground.

With such a configuration, the transformer 45 can split the input signal amplified by the carrier amplifier 13 into two split signals (first split signal and second split signal). The configuration of the transformer 45 is not limited to the configuration illustrated in FIG. 2. For example, the transformer 45 may include a pair of the input side coil and the output side coil. In this case, the input terminal 451 may be formed at one end of the input side coil, and the output terminals 452 and 453 may be respectively formed at both ends of the output side coil.

The transformer 46 is an example of a sixth transformer, and includes the input terminals 461 and 462 and an output terminal 463. The input terminal 461 is an example of a first input terminal, and is connected to the output terminal 452 of the transformer 45 with the phase shift circuit 35 interposed therebetween. The input terminal 462 is an example of a second input terminal, and is connected to the output end of the peak amplifier 23 with the phase shift circuit 36 interposed therebetween. The output terminal 463 is connected to the switches 54 and 56.

Specifically, as illustrated in FIG. 2, the transformer 46 includes an input side coil 464 and an output side coil 465.

The input side coil 464 has the input terminals 461 and 462 at both ends. That is, one end of the input side coil 464 is the input terminal 461, and is connected to the other end of the phase shift circuit 35. On the other hand, the other end of the input side coil 464 is the input terminal 462, and is connected to the other end of the phase shift circuit 36.

The output side coil 465 is configured to couple with the input side coil 464. The output side coil 465 has the output terminal 463 at one end. That is, one end of the output side coil 465 is the output terminal 463, and is connected to the switches 54 and 56. On the other hand, the other end of the output side coil 465 is connected to the switches 57 and 58.

With such a configuration, the transformer 46 can combine the two input signals (output signals of the phase shift circuits 35 and 36). The configuration of the transformer 46 is not limited to the configuration illustrated in FIG. 2. For example, the transformer 46 may include two pairs of the input side coil and the output side coil, similar to the transformer 45.

The transformer 47 is an example of a seventh transformer, and includes the input terminal 471 and the output terminals 472 and 473. The input terminal 471 is connected to the output end of the carrier amplifier 14. The output terminal 472 is an example of a first output terminal, and is connected to the input terminal 481 of the transformer 48 with the phase shift circuit 37 interposed therebetween. The output terminal 473 is an example of a second output terminal, and is connected to the input end of the peak amplifier 24.

Specifically, as illustrated in FIG. 2, the transformer 47 includes input side coils 474 and 475 and output side coils 476 and 477.

The input side coil 474 is an example of a first input side coil, and has the input terminal 471 at one end. That is, one end of the input side coil 474 is the input terminal 471, and is connected to the output end of the carrier amplifier 14. On the other hand, the other end of the input side coil 474 is connected to one end of the input side coil 475.

The input side coil 475 is an example of a second input side coil. One end of the input side coil 475 is connected to the other end of the input side coil 474. The other end of the input side coil 475 is connected to the ground.

The output side coil 476 is an example of a first output side coil, and is configured to couple with the input side coil 474. The output side coil 476 has the output terminal 472 at one end. That is, one end of the output side coil 476 is the output terminal 472, and is connected to one end of the phase shift circuit 37. On the other hand, the other end of the output side coil 476 is connected to the ground.

The output side coil 477 is an example of a second output side coil, and is configured to couple with the input side coil 475. The output side coil 477 has the output terminal 473 at one end. That is, one end of the output side coil 477 is the output terminal 473, and is connected to the input end of the peak amplifier 24. On the other hand, the other end of the output side coil 477 is connected to the ground.

With such a configuration, the transformer 47 can split the input signal amplified by the carrier amplifier 14 into two split signals (first split signal and second split signal). The configuration of the transformer 47 is not limited to the configuration illustrated in FIG. 2. For example, the transformer 47 may include a pair of the input side coil and the output side coil. In this case, the input terminal 471 may be formed at one end of the input side coil, and the output terminals 472 and 473 may be respectively formed at both ends of the output side coil.

The transformer 48 is an example of an eighth transformer, and includes the input terminals 481 and 482 and an output terminal 483. The input terminal 481 is an example of a first input terminal, and is connected to the output terminal 472 of the transformer 47 with the phase shift circuit 37 interposed therebetween. The input terminal 482 is an example of a second input terminal, and is connected to the output end of the peak amplifier 24 with the phase shift circuit 38 interposed therebetween. The output terminal 483 is connected to the switches 57 and 59.

Specifically, as illustrated in FIG. 2, the transformer 48 includes an input side coil 484 and an output side coil 485.

The input side coil 484 has the input terminals 481 and 482 at both ends. That is, one end of the input side coil 484 is the input terminal 481, and is connected to the other end of the phase shift circuit 37. On the other hand, the other end of the input side coil 484 is the input terminal 482, and is connected to the other end of the phase shift circuit 38.

The output side coil 485 is configured to couple with the input side coil 484. The output side coil 485 has the output terminal 483 at one end. That is, one end of the output side coil 485 is the output terminal 483, and is connected to the switches 57 and 59. On the other hand, the other end of the output side coil 485 is connected to the ground.

With such a configuration, the transformer 48 can combine the two input signals (output signals of the phase shift circuits 37 and 38). The configuration of the transformer 48 is not limited to the configuration illustrated in FIG. 2. For example, the transformer 48 may include two pairs of the input side coil and the output side coil, similar to the transformer 47.

The switch 51 is an example of a first switch, and is connected between the other end of the output side coil 425 of the transformer 42 and one end (that is, the output terminal 443) of the output side coil 445 of the transformer 44. Specifically, the switch 51 includes a first terminal connected to the other end of the output side coil 425 of the transformer 42, and a second terminal connected to one end of the output side coil 445 of the transformer 44. In such a connection configuration, the switch 51 can switch between the connection and the disconnection between the first terminal and the second terminal. That is, the switch 51 can switch between the connection and the disconnection between the output side coils 425 and 445.

The switch 52 is an example of a second switch, and is connected between the other end of the output side coil 425 of the transformer 42 and the ground. Specifically, the switch 52 includes a first terminal connected to the other end of the output side coil 425 of the transformer 42, and a second terminal connected to the ground. In such a connection configuration, the switch 52 can switch between the connection and the disconnection between the first terminal and the second terminal. That is, the switch 52 can switch between the connection and the disconnection between the output side coil 425 and the ground.

The switch 53 is an example of a third switch, and is connected between the output terminal 443 of the transformer 44 and the antenna connection terminal 102. Specifically, the switch 53 includes a first terminal connected to the output terminal 443 of the transformer 44, and a second terminal connected to the antenna connection terminal 102. In such a connection configuration, the switch 53 can switch between the connection and the disconnection between the first terminal and the second terminal. That is, the switch 53 can switch between the connection and the disconnection between the output terminal 443 and the antenna connection terminal 102.

Each of the switches 51 to 53 is configured as, for example, a single-pole single-throw (SPST) type switch circuit. The circuit configurations of the switches 51 to 53 are not limited to the configurations illustrated in FIG. 2. For example, the switches 51 to 53 may be configured as a single switch circuit including a first terminal connected to the other end of the output side coil 425 of the transformer 42, a second terminal connected to the ground, a third terminal connected to the output terminal 443 of the transformer 44, and a fourth terminal connected to the antenna connection terminal 102. In this case, the switch circuit need be able to connect the first terminal exclusively to the second terminal and the third terminal, and connect the third terminal to the fourth terminal.

The switch 54 is an example of a fourth switch, and is connected between the other end of the output side coil 445 of the transformer 44 and one end (that is, the output terminal 463) of the output side coil 465 of the transformer 46. Specifically, the switch 54 includes a first terminal connected to the other end of the output side coil 445 of the transformer 44, and a second terminal connected to one end of the output side coil 465 of the transformer 46. In such a connection configuration, the switch 54 can switch between the connection and the disconnection between the first terminal and the second terminal. That is, the switch 54 can switch between the connection and the disconnection between the output side coils 445 and 465.

The switch 55 is an example of a fifth switch, and is connected between the other end of the output side coil 445 of the transformer 44 and the ground. Specifically, the switch 55 includes a first terminal connected to the other end of the output side coil 445 of the transformer 44, and a second terminal connected to the ground. In such a connection configuration, the switch 55 can switch between the connection and the disconnection between the first terminal and the second terminal. That is, the switch 55 can switch between the connection and the disconnection between the output side coil 445 and the ground.

Switch 56 is an example of a sixth switch, and is connected between the output terminal 463 of the transformer 46 and the antenna connection terminal 103. Specifically, the switch 56 includes a first terminal connected to the output terminal 463 of the transformer 46, and a second terminal connected to the antenna connection terminal 103. In such a connection configuration, the switch 56 can switch between the connection and the disconnection between the first terminal and the second terminal. That is, the switch 56 can switch between the connection and the disconnection between the output terminal 463 and the antenna connection terminal 103.

Each of the switches 54 to 56 is configured as, for example, an SPST type switch circuit. The circuit configurations of the switches 54 to 56 are not limited to the configurations illustrated in FIG. 2. For example, the switches 54 to 56 may be configured as a single switch circuit including a first terminal connected to the other end of the output side coil 445 of the transformer 44, a second terminal connected to the ground, a third terminal connected to the output terminal 463 of the transformer 46, and a fourth terminal connected to the antenna connection terminal 103. In this case, the switch circuit need be able to connect the first terminal exclusively to the second terminal and the third terminal, and connect the third terminal to the fourth terminal.

The switch 57 is an example of a seventh switch, and is connected between the other end of the output side coil 465 of the transformer 46 and one end (that is, the output terminal 483) of the output side coil 485 of the transformer 48. Specifically, the switch 57 includes a first terminal connected to the other end of the output side coil 465 of the transformer 46, and a second terminal connected to one end of the output side coil 485 of the transformer 48. In such a connection configuration, the switch 57 can switch between the connection and the disconnection between the first terminal and the second terminal. That is, the switch 57 can switch between the connection and the disconnection between the output side coils 465 and 485.

The switch 58 is an example of an eighth switch, and is connected between the other end of the output side coil 465 of the transformer 46 and the ground. Specifically, the switch 58 includes a first terminal connected to the other end of the output side coil 465 of the transformer 46, and a second terminal connected to the ground. In such a connection configuration, the switch 58 can switch between the connection and the disconnection between the first terminal and the second terminal. That is, the switch 58 can switch between the connection and the disconnection between the output side coil 465 and the ground.

The switch 59 is an example of a ninth switch, and is connected between the output terminal 483 of the transformer 48 and the antenna connection terminal 104. Specifically, the switch 59 includes a first terminal connected to the output terminal 483 of the transformer 48, and a second terminal connected to the antenna connection terminal 104. In such a connection configuration, the switch 59 can switch between the connection and the disconnection between the first terminal and the second terminal. That is, the switch 59 can switch between the connection and the disconnection between the output terminal 483 and the antenna connection terminal 104.

Each of the switches 57 to 59 is configured as, for example, an SPST type switch circuit. The circuit configurations of the switches 57 to 59 are not limited to the configurations illustrated in FIG. 2. For example, the switches 57 to 59 may be configured as a single switch circuit including a first terminal connected to the other end of the output side coil 465 of the transformer 46, a second terminal connected to the ground, a third terminal connected to the output terminal 483 of the transformer 48, and a fourth terminal connected to the antenna connection terminal 104. In this case, the switch circuit need be able to connect the first terminal exclusively to the second terminal and the third terminal, and connect the third terminal to the fourth terminal.

The Doherty amplification circuit 1A represented in FIG. 2 is merely an example, and the configuration of the Doherty amplification circuit 1A is not limited to this. For example, the Doherty amplification circuit 1A may include respective band pass filters between the output terminals 423, 443, 463, and 483 of the transformers 42, 44, 46, and 48 and the antenna connection terminals 101 to 104. In addition, for example, the Doherty amplification circuit 1A may include a reception path that is connected to each of the antenna connection terminals 101 to 104. In this case, the reception path may include the band pass filter, a low noise amplifier, and the like.

In addition, for example, the Doherty amplification circuit 1A need not include a transmission path that is connected to the antennas 2c and 2d. That is, the Doherty amplification circuit 1A need not include the carrier amplifiers 13 and 14, the peak amplifiers 23 and 24, the phase shift circuits 35 to 38, the transformers 45 to 48, the switches 55 to 59, the antenna connection terminals 103 and 104, and the high frequency input terminals 113 and 114. In this case, the Doherty amplification circuit 1A cannot support 4×4 MIMO, but can support 2×2 MIMO and SISO.

In the present embodiment, the carrier amplifier and the peak amplifier that perform a Doherty operation are used in each transmission path of the Doherty amplification circuit 1A, but an amplifier that does not perform the Doherty operation may be used in a part or all of the four transmission paths. For example, the carrier amplifier 11, the peak amplifier 21, the phase shift circuits 31 and 32, and the transformers 41 and 42 may be replaced with one or a plurality of amplifiers that do not perform the Doherty operation.

### 2.3 Connection State and Flow of High Frequency Signal of Doherty Amplification Circuit 1A

A specific example of the connection state of the Doherty amplification circuit 1A according to the present embodiment and a flow of the high frequency signal in each connection state will be described.

### 2.3.1 Example of Connection State and Signal Flow in 4×4 MIMO

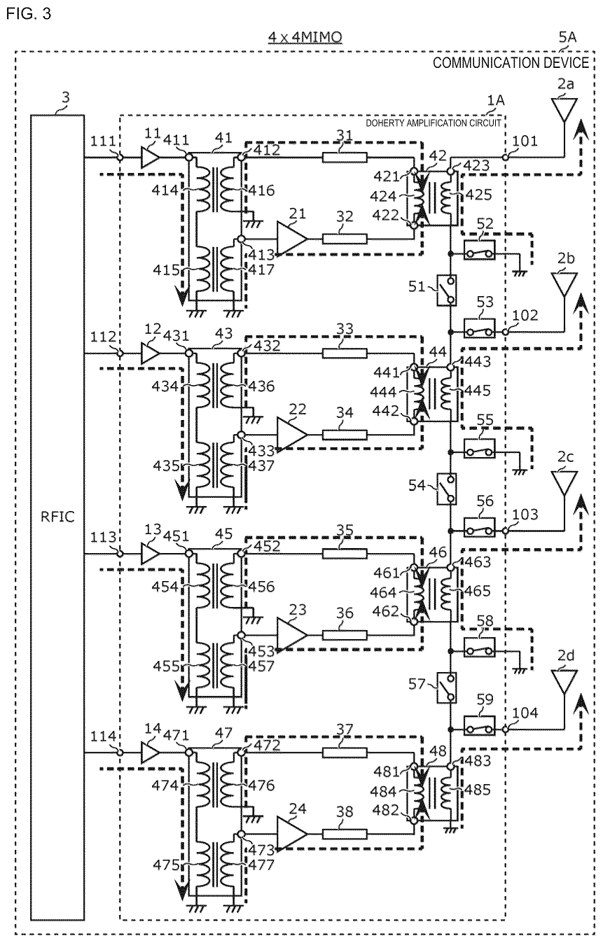

First, an example of the connection state and the signal flow in the 4×4 MIMO will be described with reference to FIG. 3. FIG. 3 is a diagram illustrating an example of the connection state and the signal flow of the Doherty amplification circuit 1A according to the present embodiment in the 4×4 MIMO.

In FIG. 3, the RFIC 3 transmits the signals from the four antennas 2a to 2d by controlling each switch of the Doherty amplification circuit 1A. Specifically, the switch 51 does not connect the other end of the output side coil 425 of the transformer 42 to one end of the output side coil 445 of the transformer 44, the switch 52 connects the other end of the output side coil 425 of the transformer 42 to the ground, and the switch 53 connects the output terminal 443 of the transformer 44 to the antenna connection terminal 102. In addition, the switch 54 does not connect the other end of the output side coil 445 of the transformer 44 to one end of the output side coil 465 of the transformer 46, the switch 55 connects the other end of the output side coil 445 of the transformer 44 to the ground, and the switch 56 connects the output terminal 463 of the transformer 46 to the antenna connection terminal 103. Further, the switch 57 does not connect the other end of the output side coil 465 of the transformer 46 to one end of the output side coil 485 of the transformer 48, the switch 58 connects the other end of the output side coil 465 of the transformer 46 to the ground, and the switch 59 connects the output terminal 483 of the transformer 48 to the antenna connection terminal 104.

As a result, the high frequency signal received by the high frequency input terminal 111 is amplified by the carrier amplifier 11. The signal amplified by the carrier amplifier 11 is split into two split signals by the transformer 41. One of the two split signals is transmitted to the transformer 42 through the phase shift circuit 31. The other of the two split signals is amplified by the peak amplifier 21 according to the power thereof, and is transmitted to the transformer 42 through the phase shift circuit 32. The two signals are combined in the transformer 42. The signal combined by the transformer 42 is output to the antenna 2a through the antenna connection terminal 101.

In addition, the high frequency signal received by the high frequency input terminal 112 is amplified by the carrier amplifier 12. The signal amplified by the carrier amplifier 12 is split into two split signals by the transformer 43. One of the two split signals is transmitted to the transformer 44 through the phase shift circuit 33. The other of the two split signals is amplified by the peak amplifier 22 according to the power thereof, and is transmitted to the transformer 44 through the phase shift circuit 34. The two signals are combined in the transformer 44. The signal combined by the transformer 44 is output to the antenna 2b through the switch 53 and the antenna connection terminal 102.

In addition, the high frequency signal received by the high frequency input terminal 113 is amplified by the carrier amplifier 13. The signal amplified by the carrier amplifier 13 is split into two split signals by the transformer 45. One of the two split signals is transmitted to the transformer 46 through the phase shift circuit 35. The other of the two split signals is amplified by the peak amplifier 23 according to the power thereof, and is transmitted to the transformer 46 through the phase shift circuit 36. The two signals are combined in the transformer 46. The signal combined by the transformer 46 is output to the antenna 2c through the switch 56 and the antenna connection terminal 103.

In addition, the high frequency signal received by the high frequency input terminal 114 is amplified by the carrier amplifier 14. The signal amplified by the carrier amplifier 14 is split into two split signals by the transformer 47. One of the two split signals is transmitted to the transformer 48 through the phase shift circuit 37. The other of the two split signals is amplified by the peak amplifier 24 according to the power thereof, and is transmitted to the transformer 48 through the phase shift circuit 38. The two signals are combined in the transformer 48. The signal combined by the transformer 48 is output to the antenna 2d through the switch 59 and the antenna connection terminal 104.

As a result, the signals amplified by the carrier amplifier 11 and the peak amplifier 21, the signals amplified by the carrier amplifier 12 and the peak amplifier 22, the signals amplified by the carrier amplifier 13 and the peak amplifier 23, and the signals amplified by the carrier amplifier 14 and the peak amplifier 24 are transmitted individually from the four antennas 2a to 2d.

### 2.3.2 First Example of Connection State and Signal Flow in 2×2 MIMO

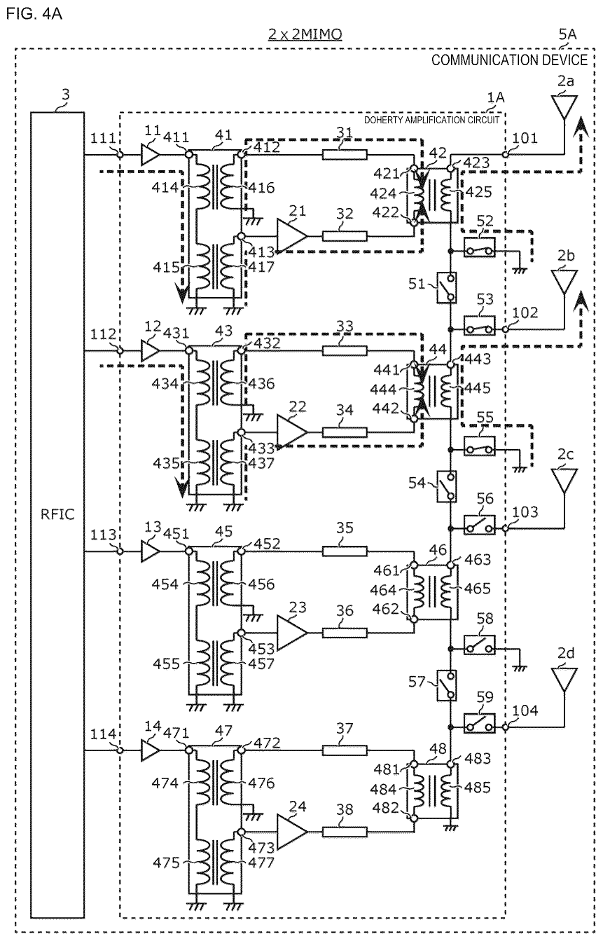

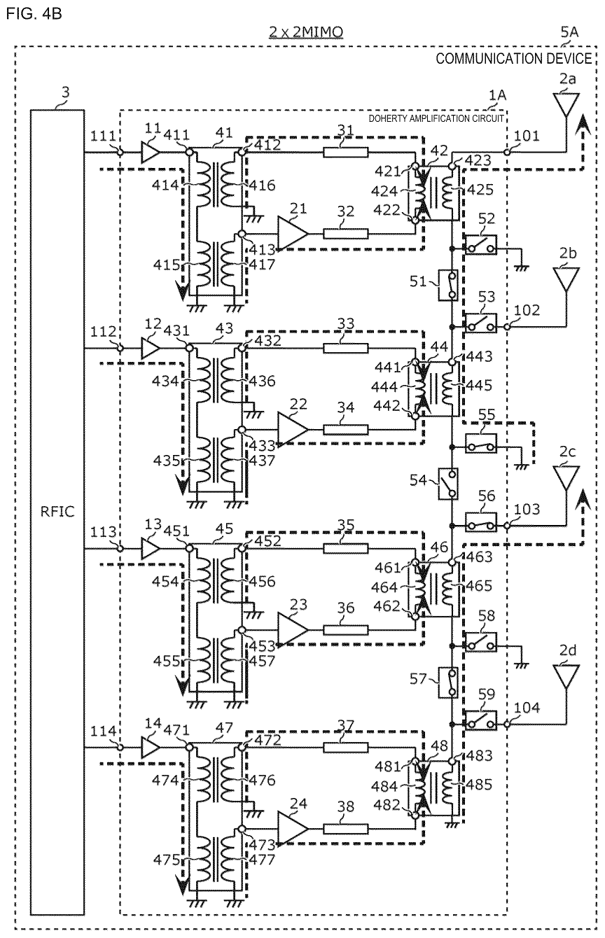

Next, the connection state and the signal flow in the 2×2 MIMO will be described with reference to FIG. 4A. FIG. 4A is a diagram illustrating a first example of the connection state and the signal flow of the Doherty amplification circuit 1A according to the present embodiment in the 2×2 MIMO.

In FIG. 4A, the RFIC 3 transmits the signals from the two antennas 2a and 2b by controlling each switch of the Doherty amplification circuit 1A. Specifically, the switch 51 does not connect the other end of the output side coil 425 of the transformer 42 to one end of the output side coil 445 of the transformer 44, the switch 52 connects the other end of the output side coil 425 of the transformer 42 to the ground, and the switch 53 connects the output terminal 443 of the transformer 44 to the antenna connection terminal 102. In addition, the switch 54 does not connect the other end of the output side coil 445 of the transformer 44 to one end of the output side coil 465 of the transformer 46, and the switch 55 connects the other end of the output side coil 445 of the transformer 44 to the ground.

As a result, the high frequency signal received by the high frequency input terminal 111 is amplified by the carrier amplifier 11. The signal amplified by the carrier amplifier 11 is split into two split signals by the transformer 41. One of the two split signals is transmitted to the transformer 42 through the phase shift circuit 31. The other of the two split signals is amplified by the peak amplifier 21 according to the power thereof, and is transmitted to the transformer 42 through the phase shift circuit 32. The two signals are combined in the transformer 42. The signal combined by the transformer 42 is output to the antenna 2a through the antenna connection terminal 101.

In addition, the high frequency signal received by the high frequency input terminal 112 is amplified by the carrier amplifier 12. The signal amplified by the carrier amplifier 12 is split into two split signals by the transformer 43. One of the two split signals is transmitted to the transformer 44 through the phase shift circuit 33. The other of the two split signals is amplified by the peak amplifier 22 according to the power thereof, and is transmitted to the transformer 44 through the phase shift circuit 34. The two signals are combined in the transformer 44. The signal combined by the transformer 44 is output to the antenna 2b through the switch 53 and the antenna connection terminal 102.

As a result, the signals amplified by the carrier amplifier 11 and the peak amplifier 21 are combined by the transformer 42 and then output from the antenna 2a. In addition, the signals amplified by the carrier amplifier 12 and the peak amplifier 22 are combined by the transformer 44 and then transmitted from the antenna 2b.

### 2.3.3 Second Example of Connection State and Signal Flow in 2×2 MIMO

Next, the connection state and the signal flow in the 2×2 MIMO will be described with reference to FIG. 4B. FIG. 4B is a diagram illustrating a second example of the connection state and the signal flow of the Doherty amplification circuit 1A according to the present embodiment in the 2×2 MIMO.

In FIG. 4B, the RFIC 3 transmits the signals from the two antennas 2a and 2c by controlling each switch of the Doherty amplification circuit 1A. Specifically, the switch 51 connects the other end of the output side coil 425 of the transformer 42 to one end of the output side coil 445 of the transformer 44, the switch 52 does not connect the other end of the output side coil 425 of the transformer 42 to the ground, and the switch 53 does not connect the output terminal 443 of the transformer 44 to the antenna connection terminal 102. In addition, the switch 54 does not connect the other end of the output side coil 445 of the transformer 44 to one end of the output side coil 465 of the transformer 46, the switch 55 connects the other end of the output side coil 445 of the transformer 44 to the ground, and the switch 56 connects the output terminal 463 of the transformer 46 to the antenna connection terminal 103. Further, the switch 57 connects the other end of the output side coil 465 of the transformer 46 to one end of the output side coil 485 of the transformer 48, the switch 58 does not connect the other end of the output side coil 465 of the transformer 46 to the ground, and the switch 59 does not connect the output terminal 483 of the transformer 48 to the antenna connection terminal 104.

As a result, the high frequency signal received by the high frequency input terminal 111 is amplified by the carrier amplifier 11. The signal amplified by the carrier amplifier 11 is split into two split signals by the transformer 41. One of the two split signals is transmitted to the transformer 42 through the phase shift circuit 31. The other of the two split signals is amplified by the peak amplifier 21 according to the power thereof, and is transmitted to the transformer 42 through the phase shift circuit 32. The two signals are combined in the transformer 42. The signal combined by the transformer 42 is output to the antenna 2a through the antenna connection terminal 101.

In addition, the high frequency signal received by the high frequency input terminal 112 is amplified by the carrier amplifier 12. The signal amplified by the carrier amplifier 12 is split into two split signals by the transformer 43. One of the two split signals is transmitted to the transformer 44 through the phase shift circuit 33. The other of the two split signals is amplified by the peak amplifier 22 according to the power thereof, and is transmitted to the transformer 44 through the phase shift circuit 34. The two signals are combined in the transformer 44. The signal combined by the transformer 44 is output to the antenna 2a through the switch 51, the output side coil 425 of the transformer 42, and the antenna connection terminal 101.

In addition, the high frequency signal received by the high frequency input terminal 113 is amplified by the carrier amplifier 13. The signal amplified by the carrier amplifier 13 is split into two split signals by the transformer 45. One of the two split signals is transmitted to the transformer 46 through the phase shift circuit 35. The other of the two split signals is amplified by the peak amplifier 23 according to the power thereof, and is transmitted to the transformer 46 through the phase shift circuit 36. The two signals are combined in the transformer 46. The signal combined by the transformer 46 is output to the antenna 2c through the switch 56 and the antenna connection terminal 103.

In addition, the high frequency signal received by the high frequency input terminal 114 is amplified by the carrier amplifier 14. The signal amplified by the carrier amplifier 14 is split into two split signals by the transformer 47. One of the two split signals is transmitted to the transformer 48 through the phase shift circuit 37. The other of the two split signals is amplified by the peak amplifier 24 according to the power thereof, and is transmitted to the transformer 48 through the phase shift circuit 38. The two signals are combined in the transformer 48. The signal combined by transformer 48 is output to antenna 2c through the switch 57, the output side coil 465 of the transformer 46, the switch 56, and the antenna connection terminal 103.

As a result, the signals amplified by the carrier amplifier 11 and the peak amplifier 21 and the signals amplified by the carrier amplifier 12 and the peak amplifier 22 are combined by the transformers 42 and 44 and then transmitted from the antenna 2a. In addition, the signals amplified by the carrier amplifier 13 and the peak amplifier 23 and the signals amplified by the carrier amplifier 14 and the peak amplifier 24 are combined by the transformers 46 and 48 and then transmitted from the antenna 2c.

### 2.3.4 First Example of Connection State and Signal Flow in SISO

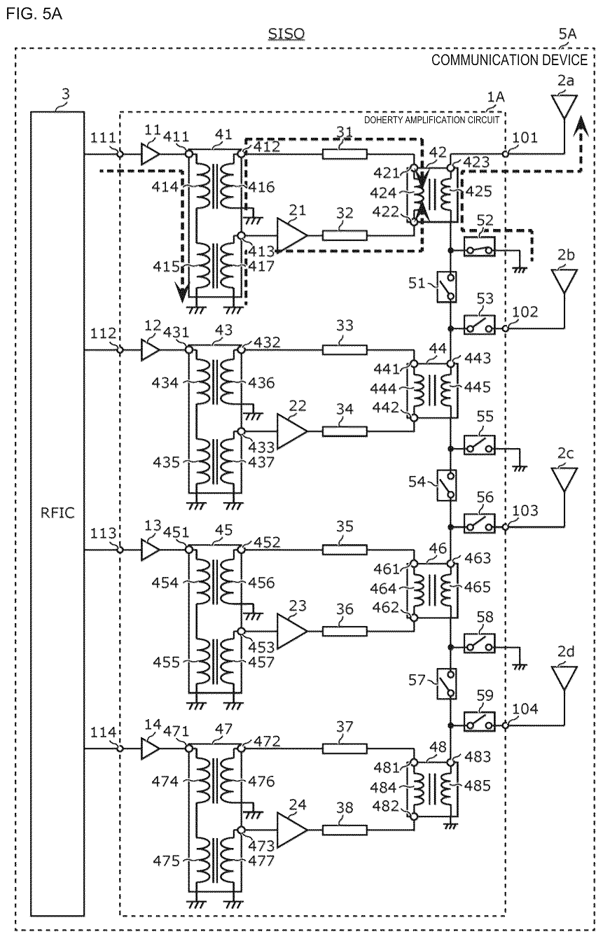

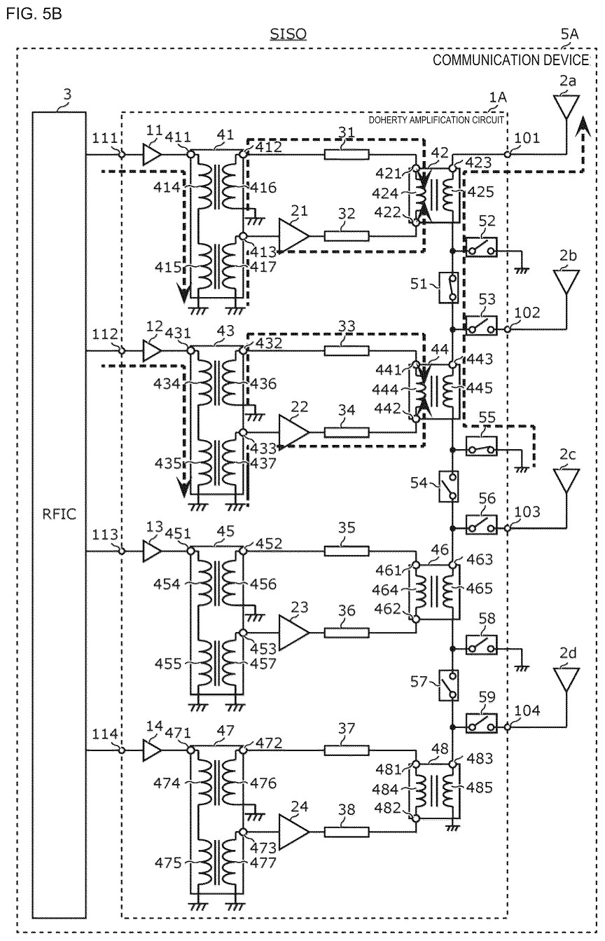

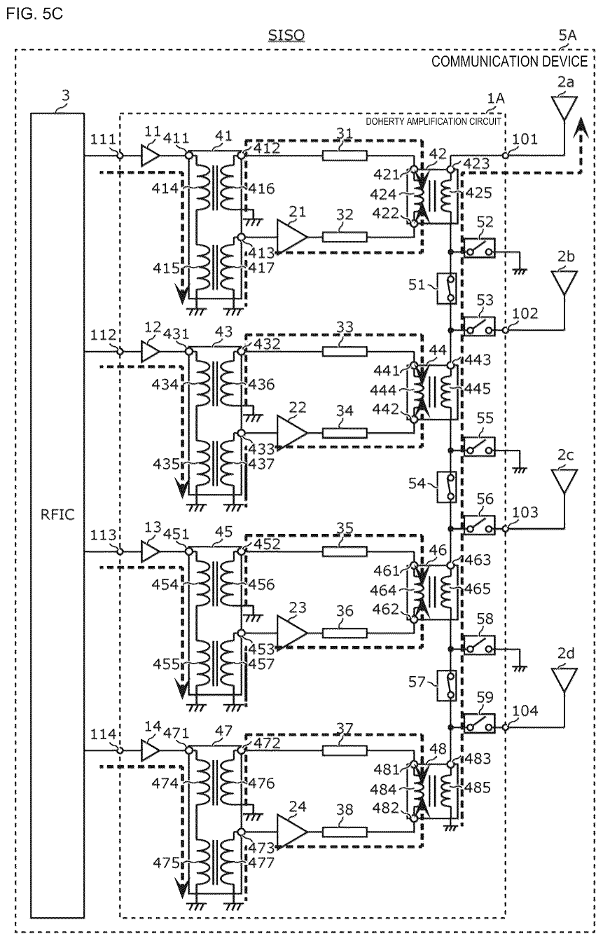

Next, the connection state and the signal flow in the SISO will be described with reference to FIG. 5A. FIG. 5A is a diagram illustrating a first example of the connection state and the signal flow of the Doherty amplification circuit 1A according to the present embodiment in the SISO.

In FIG. 5A, the RFIC 3 transmits the signal from one antenna 2a by controlling each switch of the Doherty amplification circuit 1A. Specifically, the switch 51 does not connect the other end of the output side coil 425 of the transformer 42 to one end of the output side coil 445 of the transformer 44, and the switch 52 connects the other end of the output side coil 425 of the transformer 42 to the ground.

As a result, the high frequency signal received by the high frequency input terminal 111 is amplified by the carrier amplifier 11. The signal amplified by the carrier amplifier 11 is split into two split signals by the transformer 41. One of the two split signals is transmitted to the transformer 42 through the phase shift circuit 31. The other of the two split signals is amplified by the peak amplifier 21 according to the power thereof, and is transmitted to the transformer 42 through the phase shift circuit 32. The two signals are combined in the transformer 42. The signal combined by the transformer 42 is output to the antenna 2a through the antenna connection terminal 101.

As a result, the signals amplified by the carrier amplifier 11 and the peak amplifier 21 are combined by the transformer 42 and then transmitted from one antenna 2a. The antenna used for the transmission is not limited to the antenna 2a. Any one of the four antennas 2a to 2d may be used.

### 2.3.5 Second Example of Connection State and Signal Flow in SISO

Next, the connection state and the signal flow in the SISO will be described with reference to FIG. 5B. FIG. 5B is a diagram illustrating a second example of the connection state and the signal flow of the Doherty amplification circuit 1A according to the present embodiment in the SISO.

In FIG. 5B, the RFIC 3 transmits the signal from one antenna 2a by controlling each switch of the Doherty amplification circuit 1A. Specifically, the switch 51 connects the other end of the output side coil 425 of the transformer 42 to one end of the output side coil 445 of the transformer 44, the switch 52 does not connect the other end of the output side coil 425 of the transformer 42 to the ground, and the switch 53 does not connect the output terminal 443 of the transformer 44 to the antenna connection terminal 102. In addition, the switch 54 does not connect the other end of the output side coil 445 of the transformer 44 to one end of the output side coil 465 of the transformer 46, and the switch 55 connects the other end of the output side coil 445 of the transformer 44 to the ground.

As a result, the high frequency signal received by the high frequency input terminal 111 is amplified by the carrier amplifier 11. The signal amplified by the carrier amplifier 11 is split into two split signals by the transformer 41. One of the two split signals is transmitted to the transformer 42 through the phase shift circuit 31. The other of the two split signals is amplified by the peak amplifier 21 according to the power thereof, and is transmitted to the transformer 42 through the phase shift circuit 32. The two signals are combined in the transformer 42. The signal combined by the transformer 42 is output to the antenna 2a through the antenna connection terminal 101.

In addition, the high frequency signal received by the high frequency input terminal 112 is amplified by the carrier amplifier 12. The signal amplified by the carrier amplifier 12 is split into two split signals by the transformer 43. One of the two split signals is transmitted to the transformer 44 through the phase shift circuit 33. The other of the two split signals is amplified by the peak amplifier 22 according to the power thereof, and is transmitted to the transformer 44 through the phase shift circuit 34. The two signals are combined in the transformer 44. The signal combined by the transformer 44 is output to the antenna 2a through the switch 51, the output side coil 425 of the transformer 42, and the antenna connection terminal 101.

As a result, the signals amplified by the carrier amplifier 11 and the peak amplifier 21 and the signals amplified by the carrier amplifier 12 and the peak amplifier 22 are combined by the transformers 42 and 44 and then transmitted from one antenna 2a. The antenna used for the transmission is not limited to the antenna 2a. The antenna 2b or 2c may be used.

### 2.3.6 Third Example of Connection State and Signal Flow in SISO

Next, the connection state and the signal flow in the SISO will be described with reference to FIG. 5C. FIG. 5C is a diagram illustrating a third example of the connection state and the signal flow of the Doherty amplification circuit 1A according to the present embodiment in the SISO.

In FIG. 5C, the RFIC 3 transmits the signal from one antenna 2a by controlling each switch of the Doherty amplification circuit 1A. Specifically, the switch 51 connects the other end of the output side coil 425 of the transformer 42 to one end of the output side coil 445 of the transformer 44, the switch 52 does not connect the other end of the output side coil 425 of the transformer 42 to the ground, and the switch 53 does not connect the output terminal 443 of the transformer 44 to the antenna connection terminal 102. In addition, the switch 54 connects the other end of the output side coil 445 of the transformer 44 to one end of the output side coil 465 of the transformer 46, the switch 55 does not connect the other end of the output side coil 445 of the transformer 44 to the ground, and the switch 56 does not connect the output terminal 463 of the transformer 46 to the antenna connection terminal 103. Further, the switch 57 connects the other end of the output side coil 465 of the transformer 46 to one end of the output side coil 485 of the transformer 48, the switch 58 does not connect the other end of the output side coil 465 of the transformer 46 to the ground, and the switch 59 does not connect the output terminal 483 of the transformer 48 to the antenna connection terminal 104.

As a result, the high frequency signal received by the high frequency input terminal 111 is amplified by the carrier amplifier 11. The signal amplified by the carrier amplifier 11 is split into two split signals by the transformer 41. One of the two split signals is transmitted to the transformer 42 through the phase shift circuit 31. The other of the two split signals is amplified by the peak amplifier 21 according to the power thereof, and is transmitted to the transformer 42 through the phase shift circuit 32. The two signals are combined in the transformer 42. The signal combined by the transformer 42 is output to the antenna 2a through the antenna connection terminal 101.

In addition, the high frequency signal received by the high frequency input terminal 112 is amplified by the carrier amplifier 12. The signal amplified by the carrier amplifier 12 is split into two split signals by the transformer 43. One of the two split signals is transmitted to the transformer 44 through the phase shift circuit 33. The other of the two split signals is amplified by the peak amplifier 22 according to the power thereof, and is transmitted to the transformer 44 through the phase shift circuit 34. The two signals are combined in the transformer 44. The signal combined by the transformer 44 is output to the antenna 2a through the switch 51, the output side coil 425 of the transformer 42, and the antenna connection terminal 101.

In addition, the high frequency signal received by the high frequency input terminal 113 is amplified by the carrier amplifier 13. The signal amplified by the carrier amplifier 13 is split into two split signals by the transformer 45. One of the two split signals is transmitted to the transformer 46 through the phase shift circuit 35. The other of the two split signals is amplified by the peak amplifier 23 according to the power thereof, and is transmitted to the transformer 46 through the phase shift circuit 36. The two signals are combined in the transformer 46. The signal combined by the transformer 46 is output to the antenna 2a through the switch 54, the output side coil 445 of the transformer 44, the switch 51, the output side coil 425 of the transformer 42, and the antenna connection terminal 101.

In addition, the high frequency signal received by the high frequency input terminal 114 is amplified by the carrier amplifier 14. The signal amplified by the carrier amplifier 14 is split into two split signals by the transformer 47. One of the two split signals is transmitted to the transformer 48 through the phase shift circuit 37. The other of the two split signals is amplified by the peak amplifier 24 according to the power thereof, and is transmitted to the transformer 48 through the phase shift circuit 38. The two signals are combined in the transformer 48. The signal combined by the transformer 48 is output to the antenna 2a through the switch 57, the output side coil 465 of the transformer 46, the switch 54, the output side coil 445 of the transformer 44, the switch 51, the output side coil 425 of the transformer 42, and the antenna connection terminal 101.

As a result, the signals amplified by the carrier amplifier 11 and the peak amplifier 21, the signals amplified by the carrier amplifier 12 and the peak amplifier 22, the signals amplified by the carrier amplifier 13 and the peak amplifier 23, and the signals amplified by the carrier amplifier 14 and the peak amplifier 24 are combined by the transformers 42, 44, 46, and 48 and then transmitted from one antenna 2a.

### 2.4 Effects, Etc

As described above, the Doherty amplification circuit 1A according to the present embodiment includes the carrier amplifier 11, the peak amplifier 21, the phase shift circuit 31, the phase shift circuit 32 connected to the output end of the peak amplifier 21, the transformer 41 including the input terminal 411 connected to the output end of the carrier amplifier 11, and the output terminals 412 and 413, the transformer 42 including the input terminals 421 and 422, which are respectively connected to the output terminals 412 and 413 of the transformer 41, and the output terminal 423 connected to the antenna connection terminal 101, in which the phase shift circuit 31 is connected between the output terminal 412 of the transformer 41 and the input terminal 421 of the transformer 42, and the peak amplifier 21 and the phase shift circuit 32 are connected between the output terminal 413 of the transformer 41 and the input terminal 422 of the transformer 42.

According to this, the output end of the carrier amplifier 11 is coupled with the input end of the peak amplifier 21 by the transformer 41. Therefore, since the carrier amplifier 11 and the peak amplifier 21 are not connected in parallel, it is not necessary to dispose the carrier amplifier 11 and the peak amplifier 21 side by side in the integrated circuit, and thus the degree of freedom in disposition can be increased. Further, the carrier amplifier 11 can be used in a stage preceding the peak amplifier 21, and thus the circuit scale can be reduced as compared to a configuration in which another amplifier is used in a stage preceding the carrier amplifier 11 and the peak amplifier 21 that are connected in parallel. Further, a Doherty operation can be realized, so that higher efficiency can be realized as compared to a multi-stage amplification circuit in the related art.

In addition, for example, in the Doherty amplification circuit 1A according to the present embodiment, the transformer 41 may include the input side coil 414 having the input terminal 411 of the transformer 41 at one end, the input side coil 415 having one end connected to the other end of the input side coil 414 of the transformer 41, the output side coil 416 having the output terminal 412 of the transformer 41 at one end and configured to couple with the input side coil 414 of the transformer 41, and the output side coil 417 having the output terminal 413 of the transformer 41 at one end and configured to couple with the input side coil 415 of the transformer 41, and the transformer 42 may include the input side coil 424 having the input terminal 421 and the input terminal 422 of the transformer 42 at both ends, and the output side coil 425 having the output terminal 423 of the transformer 42 at one end and configured to couple with the input side coil 424 of the transformer 42.

According to this, the first split signal and the second split signal that have the same phase are output from the output terminals 412 and 413 of the transformer 41. The phase of the second split signal is inverted by the peak amplifier 21, and is shifted by −90 degrees by the phase shift circuit 32. In the input of the transformer 42, since a phase difference of 180 degrees is preferred between the first split signal and the second split signal, a phase shift amount of the first split signal preferred for the phase shift circuit 31 is limited to −90 degrees. Therefore, a wiring length of the phase shift circuit 31 can be relatively shortened, and an overall circuit scale of the Doherty amplification circuit 1A can be reduced.

In addition, for example, the Doherty amplification circuit 1A according to the present embodiment may further include the carrier amplifier 12, the peak amplifier 22, the phase shift circuit 33, the phase shift circuit 34 connected to the output end of the peak amplifier 22, the transformer 43 including the input terminal 431 connected to the output end of the carrier amplifier 12, the output terminal 432, and the output terminal 433, and the transformer 44 including the input terminals 441 and 442, which are respectively connected to the output terminals 432 and 433 of the transformer 43, and the output terminal 443, in which the phase shift circuit 33 may be connected between the output terminal 432 of the transformer 43 and the input terminal 441 of the transformer 44, the peak amplifier 22 and the phase shift circuit 34 may be connected between the output terminal 433 of the transformer 43 and the input terminal 442 of the transformer 44, the transformer 43 may include the input side coil 434 having the input terminal 431 of the transformer 43 at one end, the input side coil 435 having one end connected to the other end of the input side coil 434 of the transformer 43, the output side coil 436 having the output terminal 432 of the transformer 43 at one end and configured to couple with the input side coil 434 of the transformer 43, and the output side coil 437 having the output terminal 433 of the transformer 43 at one end and configured to couple with the input side coil 435 of the transformer 43, the transformer 44 may include the input side coil 444 having the input terminals 441 and 442 of the transformer 44 at both ends, and the output side coil 445 having the output terminal 443 of the transformer 44 at one end and configured to couple with the input side coil 444 of the transformer 44, and the Doherty amplification circuit 1A may further include the switch 51 connected between the other end of the output side coil 425 of the transformer 42 and the output terminal 443 of the transformer 44, the switch 52 connected between the other end of the output side coil 425 of the transformer 42 and the ground, and the switch 53 connected between the output terminal 443 of the transformer 44 and the antenna connection terminal 102.

According to this, the Doherty amplification circuit 1A includes the switch 51 connected between the other end of the output side coil 425 of the transformer 42 and the output terminal 443 of the transformer 44, the switch 52 connected between the other end of the output side coil 425 of the transformer 42 and the ground, and the switch 53 connected between the output terminal 443 of the transformer 44 and the antenna connection terminal 102. Therefore, it is possible to switch between the configuration in which the signals amplified by the carrier amplifier 11 and the peak amplifier 21 and the signals amplified by the carrier amplifier 12 and the peak amplifier 22 are combined by the transformer 42 and then output from one antenna connection terminal 101 and the configuration in which the signals amplified by the carrier amplifier 11 and the peak amplifier 21 and the signals amplified by the carrier amplifier 12 and the peak amplifier 22 are combined by the transformer 42 and then individually output from the two antenna connection terminals 101 and 102.

In addition, for example, in a situation in which the Doherty amplification circuit 1A according to the present embodiment is used in the 2×2 MIMO, the switch 51 need not connect the other end of the output side coil 425 of the transformer 42 to the output terminal 443 of the transformer 44, the switch 52 may connect the other end of the output side coil 425 of the transformer 42 to the ground, and the switch 53 may connect the output terminal 443 of the transformer 44 to the antenna connection terminal 102.

According to this, it is possible to individually output the signals amplified by the carrier amplifier 11 and the peak amplifier 21 and the signals amplified by the carrier amplifier 12 and the peak amplifier 22 from the two antenna connection terminals 101 and 102 by controlling the switches 51 to 53, and it is possible to support the 2×2 MIMO.

In addition, for example, in a situation in which the Doherty amplification circuit 1A according to the present embodiment is used in the SISO, the switch 51 may connect the other end of the output side coil 425 of the transformer 42 to the output terminal 443 of the transformer 44, the switch 52 need not connect the other end of the output side coil 425 of the transformer 42 to the ground, and the switch 53 need not connect the output terminal 443 of the transformer 44 to the antenna connection terminal 102.

According to this, it is possible to combine the signals amplified by the carrier amplifier 11 and the peak amplifier 21 and the signals amplified by the carrier amplifier 12 and the peak amplifier 22 by the transformer 42 and output the combined signal from one antenna connection terminal 101 by controlling the switches 51 to 53, and it is possible to support the SISO with high output power.

In addition, for example, the Doherty amplification circuit 1A according to the present embodiment may further include the carrier amplifiers 13 and 14, the peak amplifiers 23 and 24, the phase shift circuit 35, the phase shift circuit 36 connected to the output end of the peak amplifier 23, the phase shift circuit 37, the phase shift circuit 38 connected to the output end of the peak amplifier 24, the transformer 45 including the input terminal 451 connected to the output end of the carrier amplifier 13, and the output terminals 452 and 453, the transformer 46 including the input terminals 461 and 462, which are respectively connected to the output terminals 452 and 453 of the transformer 45, and the output terminal 463, the transformer 47 including the input terminal 471 connected to the output end of the carrier amplifier 14, and the output terminals 472 and 473, and the transformer 48 including the input terminals 481 and 482, which are respectively connected to the output terminals 472 and 473 of the transformer 47, and the output terminal 483, in which the phase shift circuit 35 may be connected between the output terminal 452 of the transformer 45 and the input terminal 461 of the transformer 46, the peak amplifier 23 and the phase shift circuit 36 are connected between the output terminal 453 of the transformer 45 and the input terminal 462 of the transformer 46, the phase shift circuit 37 is connected between the output terminal 472 of the transformer 47 and the input terminal 481 of the transformer 48, the peak amplifier 24 and the phase shift circuit 38 are connected between the output terminal 473 of the transformer 47 and the input terminal 482 of the transformer 48, the transformer 45 may include the input side coil 454 having the input terminal 451 of the transformer 45 at one end, the input side coil 455 having one end connected to the other end of the input side coil 454 of the transformer 45, the output side coil 456 having the output terminal 452 of the transformer 45 at one end and configured to couple with the input side coil 454 of the transformer 45, and the output side coil 457 having the output terminal 453 of the transformer 45 at one end and configured to couple with the input side coil 455 of the transformer 45, the transformer 46 may include the input side coil 464 having the input terminals 461 and 462 of the transformer 46 at both ends, and the output side coil 465 having the output terminal 463 of the transformer 46 at one end and configured to couple with the input side coil 464 of the transformer 46, the transformer 47 may include the input side coil 474 having the input terminal 471 of the transformer 47 at one end, the input side coil 475 having one end connected to the other end of the input side coil 474 of the transformer 47, the output side coil 476 having the output terminal 472 of the transformer 47 at one end and configured to couple with the input side coil 474 of the transformer 47, and the output side coil 477 having the output terminal 473 of the transformer 47 at one end and configured to couple with the input side coil 475 of the transformer 47, the transformer 48 may include the input side coil 484 having the input terminals 481 and 482 of the transformer 48 at both ends, and the output side coil 485 having the output terminal 483 of the transformer 48 at one end and configured to couple with the input side coil 484 of the transformer 48, and the Doherty amplification circuit may further include the switch 54 connected between the other end of the output side coil 445 of the transformer 44 and the output terminal 463 of the transformer 46, the switch 55 connected between the other end of the output side coil 445 of the transformer 44 and the ground, the switch 56 connected between the output terminal 463 of the transformer 46 and the antenna connection terminal 103, the switch 57 connected between the other end of the output side coil 465 of the transformer 46 and the output terminal 483 of the transformer 48, the switch 58 connected between the other end of the output side coil 465 of the transformer 46 and the ground, and the switch 59 connected between the output terminal 483 of the transformer 48 and the antenna connection terminal 104.

According to this, it is possible to switch between the configuration in which the four signals amplified by the carrier amplifiers 11 to 14 and the peak amplifiers 21 to 24 are combined in any combination of the transformers 42, 44, and 46 and then output from one to three antenna connection terminals 101 to 103 and the configuration in which the four signals amplified by the carrier amplifiers 11 to 14 and the peak amplifiers 21 to 24 are combined and then individually output from the antenna connection terminals 101 to 104.

In addition, for example, in a situation in which the Doherty amplification circuit 1A according to the present embodiment is used in the 4×4 MIMO, the switch 51 need not connect the other end of the output side coil 425 of the transformer 42 to the output terminal 443 of the transformer 44, the switch 52 may connect the other end of the output side coil 425 of the transformer 42 to the ground, the switch 53 may connect the output terminal 443 of the transformer 44 to the antenna connection terminal 102, the switch 54 need not connect the other end of the output side coil 445 of the transformer 44 to the output terminal 463 of the transformer 46, the switch 55 may connect the other end of the output side coil 445 of the transformer 44 to the ground, the switch 56 may connect the output terminal 463 of the transformer 46 to the antenna connection terminal 103, the switch 57 need not connect the other end of the output side coil 465 of the transformer 46 to the output terminal 483 of the transformer 48, the switch 58 may connect the other end of the output side coil 465 of the transformer 46 to the ground, and the switch 59 may connect the output terminal 483 of the transformer 48 to the antenna connection terminal 104.

According to this, it is possible to individually output the signals amplified by the carrier amplifier 11 and the peak amplifier 21, the signals amplified by the carrier amplifier 12 and the peak amplifier 22, the signals amplified by the carrier amplifier 13 and the peak amplifier 23, and the signals amplified by the carrier amplifier 14 and the peak amplifier 24 from the four antenna connection terminals 101 to 104 by controlling the switches 51 to 59, it is possible to support the 4×4 MIMO.

In addition, for example, in a situation in which the Doherty amplification circuit 1A according to the present embodiment is used in the 2×2 MIMO, the switch 51 may connect the other end of the output side coil 425 of the transformer 42 to the output terminal 443 of the transformer 44, the switch 52 need not connect the other end of the output side coil 425 of the transformer 42 to the ground, the switch 53 need not connect the output terminal 443 of the transformer 44 to the antenna connection terminal 102, the switch 54 need not connect the other end of the output side coil 445 of the transformer 44 to the output terminal 463 of the transformer 46, the switch 55 may connect the other end of the output side coil 445 of the transformer 44 to the ground, the switch 56 may connect the output terminal 463 of the transformer 46 to the antenna connection terminal 103, the switch 57 may connect the other end of the output side coil 465 of the transformer 46 to the output terminal 483 of the transformer 48, the switch 58 need not connect the other end of the output side coil 465 of the transformer 46 to the ground, and the switch 59 need not connect the output terminal 483 of the transformer 48 to the antenna connection terminal 104.

According to this, the signals amplified by the carrier amplifier 11 and the peak amplifier 21 and the signals amplified by the carrier amplifier 12 and the peak amplifier 22 can be combined and then output from the antenna connection terminal 101, and the signals amplified by the carrier amplifier 13 and the peak amplifier 23 and the signals amplified by the carrier amplifier 14 and the peak amplifier 24 can be combined and then output from the antenna connection terminal 103, by controlling the switches 51 to 59. Therefore, it is possible to support the 2×2 MIMO with relatively high output power.

In addition, for example, in a situation in which the Doherty amplification circuit 1A according to the present embodiment is used in the SISO, the switch 51 may connect the other end of the output side coil 425 of the transformer 42 to the output terminal 443 of the transformer 44, the switch 52 need not connect the other end of the output side coil 425 of the transformer 42 to the ground, the switch 53 need not connect the output terminal 443 of the transformer 44 to the antenna connection terminal 102, the switch 54 may connect the other end of the output side coil 445 of the transformer 44 to the output terminal 463 of the transformer 46, the switch 55 need not connect the other end of the output side coil 445 of the transformer 44 to the ground, the switch 56 need not connect the output terminal 463 of the transformer 46 to the antenna connection terminal 103, the switch 57 may connect the other end of the output side coil 465 of the transformer 46 to the output terminal 483 of the transformer 48, the switch 58 need not connect the other end of the output side coil 465 of the transformer 46 to the ground, and the switch 59 need not connect the output terminal 483 of the transformer 48 to the antenna connection terminal 104.

According to this, the signals amplified by the carrier amplifier 11 and the peak amplifier 21, the signals amplified by the carrier amplifier 12 and the peak amplifier 22, the signals amplified by the carrier amplifier 13 and the peak amplifier 23, and the signals amplified by the carrier amplifier 14 and the peak amplifier 24 can be combined and then output from the antenna connection terminal 101 by controlling the switches 51 to 59. Therefore, it is possible to support the SISO with relatively high output power.

Further, the Doherty amplification circuit 1A according to the present embodiment includes the carrier amplifier 11 configured to amplify the input signal, the transformer 41 configured to split the input signal amplified by the carrier amplifier 11 into the first split signal and the second split signal, the phase shift circuit 31 configured to adjust the phase of the first split signal, the peak amplifier 21 configured to amplify the second split signal, the phase shift circuit 32 configured to adjust the phase of the second split signal amplified by the peak amplifier 21, and the transformer 42 configured to combine the first split signal having the phase adjusted by the phase shift circuit 31 and the second split signal having the phase adjusted by the phase shift circuit 32.

According to this, a part (second split signal) of the input signal amplified by the carrier amplifier 11 is amplified by the peak amplifier 21. Therefore, the carrier amplifier 11 and the peak amplifier 21 can be connected in series, and it is not necessary to dispose the carrier amplifier 11 and the peak amplifier 21 side by side in the integrated circuit, so that the degree of freedom in disposition can be increased. Further, the carrier amplifier 11 can be used in a stage preceding the peak amplifier 21, and thus the circuit scale can be reduced as compared to a configuration in which another amplifier is used in a stage preceding the carrier amplifier 11 and the peak amplifier 21 that are connected in parallel. Further, a Doherty operation can be realized, so that higher efficiency can be realized as compared to a multi-stage amplification circuit in the related art.

### Embodiment 3

Hereinafter, Embodiment 3 will be described. A Doherty amplification circuit according to the present embodiment is mainly different from the Doherty amplification circuit according to Embodiment 1 in that an output end of one carrier amplifier is coupled with input ends of two peak amplifiers. Hereinafter, the Doherty amplification circuit according to the present embodiment will be described with reference to the accompanying drawings, focusing on the difference from Embodiments 1 and 2.

A circuit configuration of the communication device 5B according to the present embodiment is the same as the circuit configuration of the communication device 5 according to Embodiment 1, except that the communication device 5B includes a Doherty amplification circuit 1B instead of the Doherty amplification circuit 1, and thus the description thereof will be omitted.

### 3.1 Circuit Configuration of Doherty Amplification Circuit 1B

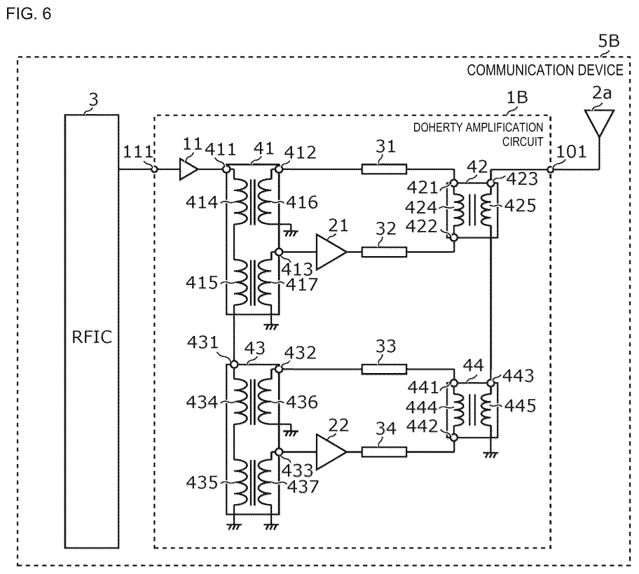

A circuit configuration of the Doherty amplification circuit 1B included in the communication device 5B according to the present embodiment will be described with reference to FIG. 6. FIG. 6 is a circuit configuration diagram of the communication device 5B according to the present embodiment. The Doherty amplification circuit 1B includes a carrier amplifier 11, peak amplifiers 21 and 22, phase shift circuits 31 to 34, transformers 41 to 44, an antenna connection terminal 101, and a high frequency input terminal 111.

In the present embodiment, the other end of the input side coil 415 of the transformer 41 is connected to one end of the input side coil 434 of the transformer 43. In other words, the input terminal 431 of the transformer 43 is connected to the output end of the carrier amplifier 11 with the input side coils 414 and 415 of the transformer 41 interposed therebetween.

In addition, the other end of the output side coil 425 of the transformer 42 is connected to one end of the output side coil 445 of the transformer 44. In other words, the output terminal 443 of the transformer 44 is connected to the antenna connection terminal 101 with the output side coil 425 of the transformer 42 interposed therebetween.

With such a configuration, the Doherty amplification circuit 1B can amplify a part of the signal amplified by the carrier amplifier 11 by using the two peak amplifiers 21 and 22.

The Doherty amplification circuit 1B represented in FIG. 6 is merely an example, and the configuration of the Doherty amplification circuit 1B is not limited to this. For example, the Doherty amplification circuit 1B may include a band pass filter between the output terminal 423 of the transformer 42 and the antenna connection terminal 101. In addition, for example, the Doherty amplification circuit 1B may include a reception path that is connected to the antenna connection terminal 101. In this case, the reception path may include the band pass filter, a low noise amplifier, and the like.

### 3.2 Effects, Etc

As described above, the Doherty amplification circuit 1B according to the present embodiment includes the carrier amplifier 11, the peak amplifier 21, the phase shift circuit 31, the phase shift circuit 32 connected to the output end of the peak amplifier 21, the transformer 41 including the input terminal 411 connected to the output end of the carrier amplifier 11, and the output terminals 412 and 413, the transformer 42 including the input terminals 421 and 422, which are respectively connected to the output terminals 412 and 413 of the transformer 41, and the output terminal 423 connected to the antenna connection terminal 101, in which the phase shift circuit 31 is connected between the output terminal 412 of the transformer 41 and the input terminal 421 of the transformer 42, and the peak amplifier 21 and the phase shift circuit 32 are connected between the output terminal 413 of the transformer 41 and the input terminal 422 of the transformer 42.

According to this, the output end of the carrier amplifier 11 is coupled with the input end of the peak amplifier 21 by the transformer 41. Therefore, since the carrier amplifier 11 and the peak amplifier 21 are not connected in parallel, it is not necessary to dispose the carrier amplifier 11 and the peak amplifier 21 side by side in the integrated circuit, and thus the degree of freedom in disposition can be increased. Further, the carrier amplifier 11 can be used in a stage preceding the peak amplifier 21, and thus the circuit scale can be reduced as compared to a configuration in which another amplifier is used in a stage preceding the carrier amplifier 11 and the peak amplifier 21 that are connected in parallel. Further, a Doherty operation can be realized, so that higher efficiency can be realized as compared to a multi-stage amplification circuit in the related art.

In addition, for example, in the Doherty amplification circuit 1B according to the present embodiment, the transformer 41 may include the input side coil 414 having the input terminal 411 of the transformer 41 at one end, the input side coil 415 having one end connected to the other end of the input side coil 414 of the transformer 41, the output side coil 416 having the output terminal 412 of the transformer 41 at one end and configured to couple with the input side coil 414 of the transformer 41, and the output side coil 417 having the output terminal 413 of the transformer 41 at one end and configured to couple with the input side coil 415 of the transformer 41, and the transformer 42 may include the input side coil 424 having the input terminal 421 and the input terminal 422 of the transformer 42 at both ends, and the output side coil 425 having the output terminal 423 of the transformer 42 at one end and configured to couple with the input side coil 424 of the transformer 42.

According to this, the first split signal and the second split signal that have the same phase are output from the output terminals 412 and 413 of the transformer 41. The phase of the second split signal is inverted by the peak amplifier 21, and is shifted by −90 degrees by the phase shift circuit 32. In the input of the transformer 42, since a phase difference of 180 degrees is preferred between the first split signal and the second split signal, a phase shift amount of the first split signal preferred for the phase shift circuit 31 is limited to −90 degrees. Therefore, a wiring length of the phase shift circuit 31 can be relatively shortened, and an overall circuit scale of the Doherty amplification circuit 1B can be reduced.

In addition, for example, the Doherty amplification circuit 1B according to the present embodiment may further include the peak amplifier 22, the phase shift circuit 33, the phase shift circuit 34 connected to the output end of the peak amplifier 22, the transformer 43 including the input terminal 431 connected to the other end of the input side coil 415 of the transformer 41, and the output terminals 432 and 433, and the transformer 44 including the input terminals 441 and 442, which are respectively connected to the output terminals 432 and 433 of the transformer 43, and the output terminal 443, in which the phase shift circuit 33 may be connected between the output terminal 432 of the transformer 43 and the input terminal 441 of the transformer 44, the peak amplifier 22 and the phase shift circuit 34 may be connected between the output terminal 433 of the transformer 43 and the input terminal 442 of the transformer 44, the transformer 43 may include the input side coil 434 having the input terminal 431 of the transformer 43 at one end, the input side coil 435 having one end connected to the other end of the input side coil 434 of the transformer 43, the output side coil 436 having the output terminal 432 of the transformer 43 at one end and configured to couple with the input side coil 434 of the transformer 43, and the output side coil 437 having the output terminal 433 of the transformer 43 at one end and configured to couple with the input side coil 435 of the transformer 43, the transformer 44 may include the input side coil 444 having the input terminals 441 and 442 of the transformer 44 at both ends, and the output side coil 445 having the output terminal 443 of the transformer 44 at one end and configured to couple with the input side coil 444 of the transformer 44, and the output terminal 443 of the transformer 44 may be connected to the other end of the output side coil 425 of the transformer 42.

According to this, the output end of the carrier amplifier 11 is coupled with the input end of the peak amplifier 21 by the transformer 41, and the output end of the carrier amplifier 11 is coupled with the input end of the peak amplifier 22 by the transformer 43. Therefore, a two-stage three-way Doherty amplifier can be realized by using the carrier amplifier 11 in a stage preceding the peak amplifiers 21 and 22. Therefore, by appropriately operating the peak amplifiers 21 and 22, the back-off of the Doherty amplification circuit 1B can be increased, so that the high efficiency and the reduction in the circuit scale can be realized.

Further, the Doherty amplification circuit 1B according to the present embodiment includes the carrier amplifier 11 configured to amplify the input signal, the transformer 41 configured to split the input signal amplified by the carrier amplifier 11 into the first split signal and the second split signal, the phase shift circuit 31 configured to adjust the phase of the first split signal, the peak amplifier 21 configured to amplify the second split signal, the phase shift circuit 32 configured to adjust the phase of the second split signal amplified by the peak amplifier 21, and the transformer 42 configured to combine the first split signal having the phase adjusted by the phase shift circuit 31 and the second split signal having the phase adjusted by the phase shift circuit 32.

According to this, a part (second split signal) of the input signal amplified by the carrier amplifier 11 is amplified by the peak amplifier 21. Therefore, the carrier amplifier 11 and the peak amplifier 21 can be connected in series, and it is not necessary to dispose the carrier amplifier 11 and the peak amplifier 21 side by side in the integrated circuit, so that the degree of freedom in disposition can be increased. Further, the carrier amplifier 11 can be used in a stage preceding the peak amplifier 21, and thus the circuit scale can be reduced as compared to a configuration in which another amplifier is used in a stage preceding the carrier amplifier 11 and the peak amplifier 21 that are connected in parallel. Further, a Doherty operation can be realized, so that higher efficiency can be realized as compared to a multi-stage amplification circuit in the related art.

### Embodiment 4

Hereinafter, Embodiment 4 will be described. A Doherty amplification circuit according to the present embodiment is mainly different from the Doherty amplification circuit according to Embodiment 3 in that an input end of one peak amplifier is coupled with an output end of one carrier amplifier, and an input end of another peak amplifier is coupled with an output end of the one peak amplifier. Hereinafter, the communication device and the Doherty amplification circuit according to the present embodiment will be described with reference to the accompanying drawings, focusing on the difference from Embodiment 3.

A circuit configuration of the communication device 5C according to the present embodiment is the same as the circuit configuration of the communication device 5 according to Embodiment 1, except that the communication device 5C includes a Doherty amplification circuit 1C instead of the Doherty amplification circuit 1, and thus the description thereof will be omitted.

### 4.1 Circuit Configuration of Doherty Amplification Circuit 1C

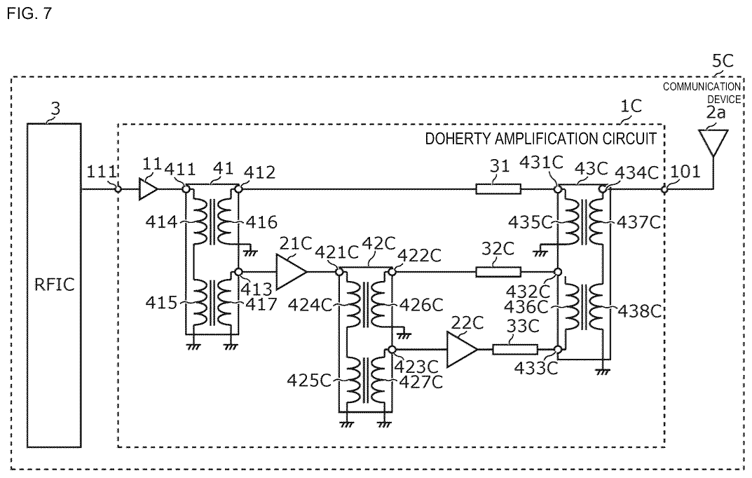

A circuit configuration of the Doherty amplification circuit 1C included in the communication device 5C according to the present embodiment will be described with reference to FIG. 7. FIG. 7 is a circuit configuration diagram of the communication device 5C according to the present embodiment. The Doherty amplification circuit 1C includes a carrier amplifier 11, peak amplifiers 21C and 22C, phase shift circuits 31, 32C, and 33C, transformers 41, 42C, and 43C, an antenna connection terminal 101, and a high frequency input terminal 111.

The peak amplifier 21C is an example of a first peak amplifier, and is connected between the transformers 41 42C. Specifically, an input end of the peak amplifier 21C is connected to the output terminal 413 of the transformer 41, and an output end of the peak amplifier 21C is connected to an input terminal 421C of the transformer 42C. The peak amplifier 21C can operate, for example, in a class-C to amplify a part of the signal amplified by the carrier amplifier 11.

The peak amplifier 22C is an example of a second peak amplifier, and is connected between the transformers 42C and 43C. Specifically, an input end of the peak amplifier 22C is connected to an output terminal 423C of the transformer 42C, and an output end of the peak amplifier 22C is connected to an input terminal 433C of the transformer 43C with the phase shift circuit 33C interposed therebetween. The peak amplifier 22C can operate, for example, in a class-C to amplify a part of the signal amplified by the peak amplifier 21C.

The phase shift circuit 32C is an example of a second phase shift circuit, and is connected between the transformers 42C and 43C. Specifically, one end of the phase shift circuit 32C is connected to the output terminal 422C of the transformer 42C, and the other end of the phase shift circuit 32C is connected to the input terminal 432C of the transformer 43C.

The phase shift circuit 33C is an example of a third phase shift circuit, and is connected between the transformers 42C and 43C. Specifically, one end of the phase shift circuit 33C is connected to the output end of the peak amplifier 22C, and the other end of the phase shift circuit 33C is connected to the input terminal 433C of the transformer 43C. That is, the peak amplifier 22C and the phase shift circuit 33C are connected between the output terminal 423C of the transformer 42C and the input terminal 433C of the transformer 43C.

Each of the phase shift circuits 32C and 33C can adjust a phase of the input signal. Specifically, each of the phase shift circuits 32C and 33C can shift the phase of the input signal by −90 degrees (delay the phase of the input signal by −90 degrees). As the phase shift circuits 32C and 33C, for example, a quarter wavelength transmission line can be used. The phase shift circuits 32C and 33C may include an inductor and/or a capacitor. As a result, the phase shift circuits 32C and 33C can shorten a transmission line length. A phase adjustment amount in each of the phase shift circuits 32C and 33C is not limited to −90 degrees.

The transformer 42C is an example of a second transformer, and includes the input terminal 421C and the output terminals 422C and 423C. The input terminal 421C is connected to the output end of the peak amplifier 21C. Output terminal 422C is an example of a first output terminal, and is connected to the input terminal 432C of the transformer 43C with the phase shift circuit 32C interposed therebetween. The output terminal 423C is an example of a second output terminal, and is connected to the input end of the peak amplifier 22C.

Specifically, as illustrated in FIG. 7, the transformer 42C includes input side coils 424C and 425C and output side coils 426C and 427C.

The input side coil 424C is an example of a first input side coil, and has the input terminal 421C at one end. That is, one end of the input side coil 424C is the input terminal 421C, and is connected to the output end of the peak amplifier 21C. On the other hand, the other end of the input side coil 424C is connected to one end of the input side coil 425C.

The input side coil 425C is an example of a second input side coil. One end of the input side coil 425C is connected to the other end of the input side coil 424C. The other end of the input side coil 425C is connected to the ground.

The output side coil 426C is an example of a first output side coil, and is configured to couple with the input side coil 424C. The output side coil 426C has the output terminal 422C at one end. That is, one end of the output side coil 426C is the output terminal 422C, and is connected to one end of the phase shift circuit 32C. The other end of the output side coil 426C is connected to the ground.

The output side coil 427C is an example of a second output side coil, and is configured to couple with the input side coil 425C. The output side coil 427C has the output terminal 423C at one end. That is, one end of the output side coil 427C is the output terminal 423C, and is connected to the input end of the peak amplifier 22C. On the other hand, the other end of the output side coil 427C is connected to the ground.

With such a configuration, the transformer 42C can split the input signal amplified by the peak amplifier 21C into two split signals (third split signal and fourth split signal). The configuration of the transformer 42C is not limited to the configuration illustrated in FIG. 7. For example, the transformer 42C may include a pair of the input side coil and the output side coil. In this case, the input terminal 421C may be formed at one end of the input side coil, and the output terminals 422C and 423C may be formed at both ends of the output side coil.

The transformer 43C is an example of a third transformer, and includes input terminals 431C to 433C and an output terminal 434C. The input terminal 431C is an example of a first input terminal, and is connected to the output terminal 412 of the transformer 41 with the phase shift circuit 31 interposed therebetween. The input terminal 432C is an example of a second input terminal, and is connected to the output terminal 422C of the transformer 42C with the phase shift circuit 32C interposed therebetween. The input terminal 433C is an example of a third input terminal, and is connected to the output end of the peak amplifier 22C with the phase shift circuit 33C interposed therebetween. The output terminal 434C is connected to the antenna connection terminal 101.

Specifically, as illustrated in FIG. 7, the transformer 43C includes input side coils 435C and 436C and output side coils 437C and 438C.

The input side coil 435C is an example of a first input side coil, and has the input terminal 431C at one end. That is, one end of the input side coil 435C is the input terminal 431C, and is connected to the other end of the phase shift circuit 31. On the other hand, the other end of the input side coil 435C is connected to the ground.

The input side coil 436C is an example of a second input side coil, and has the input terminals 432C and 433C at both ends. That is, one end of the input side coil 436C is the input terminal 432C, and is connected to the other end of the phase shift circuit 32C. On the other hand, the other end of the input side coil 436C is the input terminal 433C, and is connected to the other end of the phase shift circuit 33C.

The output side coil 437C is an example of a first output side coil, and is configured to couple with the input side coil 435C. The output side coil 437C has the output terminal 434C at one end. That is, one end of the output side coil 437C is the output terminal 434C, and is connected to the antenna connection terminal 101. On the other hand, the other end of the output side coil 437C is connected to one end of the output side coil 438C.

The output side coil 438C is an example of a second output side coil, and is configured to couple with the input side coil 436C. One end of the output side coil 438C is connected to the other end of the output side coil 437C. On the other hand, the other end of the output side coil 438C is connected to the ground.

With such a configuration, the transformer 43C can combine the three input signals (output signals of the phase shift circuits 31, 32C, and 33C). The configuration of the transformer 43C is not limited to the configuration illustrated in FIG. 7.

The Doherty amplification circuit 1C illustrated in FIG. 7 is merely an example, and the configuration of the Doherty amplification circuit 1C is not limited to this. For example, the Doherty amplification circuit 1C may include a band pass filter between the output terminal 434C of the transformer 43C and the antenna connection terminal 101. In addition, for example, the Doherty amplification circuit 1C may include a reception path that is connected to the antenna connection terminal 101. In this case, the reception path may include the band pass filter, a low noise amplifier, and the like.

### 4.2 Effects, Etc

As described above, the Doherty amplification circuit 1C according to the present embodiment includes the carrier amplifier 11, the peak amplifiers 21C and 22C, the phase shift circuits 31 and 32C, the phase shift circuit 33C connected to the output end of the peak amplifier 22C, the transformer 41 including the input terminal 411 connected to the output end of the carrier amplifier 11, and the output terminals 412 and 413, the transformer 42C including the input terminal 421C connected to the output terminal 413 of the transformer 41, and the output terminals 422C and 423C, and the transformer 43C including the input terminals 431C to 433C, which are respectively connected to the output terminal 412 of the transformer 41 and the output terminals 422C and 423C of the transformer 42C, and the output terminal 434C connected to the antenna connection terminal 101, in which the phase shift circuit 31 is connected between the output terminal 412 of the transformer 41 and the input terminal 431C of the transformer 43C, the peak amplifier 21C is connected between the output terminal 413 of the transformer 41 and the input terminal 421C of the transformer 42C, the phase shift circuit 32C is connected between the output terminal 422C of the transformer 42C and the input terminal 432C of the transformer 43C, and the peak amplifier 22C and the phase shift circuit 33C are connected between the output terminal 423C of the transformer 42C and the input terminal 433C of the transformer 43C.

According to this, the output end of the carrier amplifier 11 is coupled with the input end of the peak amplifier 21C by the transformer 41, and the output end of the peak amplifier 21C is coupled with the input end of the peak amplifier 22C by the transformer 42C. Therefore, a three-stage three-way Doherty amplifier can be realized by using the peak amplifier 21C in a stage preceding the peak amplifier 22C and using the carrier amplifier 11 in a stage preceding the peak amplifier 21C. Therefore, by appropriately operating the peak amplifiers 21C and 22C, the back-off of the Doherty amplification circuit 1C can be increased, so that the high efficiency and the reduction in the circuit scale can be realized.

In addition, for example, in the Doherty amplification circuit 1C according to the present embodiment, the transformer 41 may include the input side coil 414 having the input terminal 411 of the transformer 41 at one end, the input side coil 415 having one end connected to the other end of the input side coil 414 of the transformer 41, the output side coil 416 having the output terminal 412 of the transformer 41 at one end and configured to couple with the input side coil 414 of the transformer 41, and the output side coil 417 having the output terminal 413 of the transformer 41 at one end and configured to couple with the input side coil 415 of the transformer 41, the transformer 42C may include the input side coil 424C having the input terminal 421C of the transformer 42C at one end, the input side coil 425C having one end connected to the other end of the input side coil 424C of the transformer 42C, the output side coil 426C having the output terminal 422C of the transformer 42C at one end and configured to couple with the input side coil 424C of the transformer 42C, and the output side coil 427C having the output terminal 423C of the transformer 42C at one end and configured to couple with the input side coil 425C of the transformer 42C, and the transformer 43C may include the input side coil 435C having the input terminal 431C of the transformer 43C at one end, the input side coil 436C having the input terminals 432C and 433C of the transformer 43C at both ends, the output side coil 437C having the output terminal 434C of the transformer 43C at one end and configured to couple with the input side coil 435C of the transformer 43C, and the output side coil 438C having one end connected to the other end of the output side coil 437C of the transformer 43C and configured to couple with the input side coil 436C of the transformer 43C.

According to this, by using transformers 41, 42C, and 43C, the wiring lengths of the phase shift circuits 31, 32C, and 33C can be relatively shortened, and an overall circuit scale of the Doherty amplification circuit 1C can be reduced.

### OTHER EMBODIMENTS

Although the Doherty amplification circuit according to the present disclosure has been described based on the embodiments, the Doherty amplification circuit according to the present disclosure is not limited to the embodiments described above. The present disclosure also includes another embodiment realized by combining any of the constituent elements in the embodiments described above, a modification example obtained by various modifications conceived by those skilled in the art within a range not departing from the gist of the present disclosure with respect to the embodiments described above, or various devices incorporating the Doherty amplification circuit described above.

For example, in the circuit configurations of the Doherty amplification circuits according to the embodiments described above, other circuit elements, wirings, and the like may be inserted into the path connecting each circuit element and the signal path disclosed in the drawings. For example, an impedance matching circuit may be inserted between the transformer 42 and the antenna connection terminal 101.

In addition, for example, Embodiment 2 and Embodiment 3 or 4 may be combined with each other. That is, the Doherty amplification circuit 1B or 1C according to Embodiment 3 or 4 may be configured to switch between the MIMO and the SISO as in Embodiment 2.

Hereinafter, the features of the Doherty amplification circuit described based on each of the embodiments will be described.
<1> A Doherty amplification circuit including: a first carrier amplifier; a first peak amplifier; a first phase shift circuit; a second phase shift circuit connected to an output end of the first peak amplifier; a first transformer including an input terminal connected to an output end of the first carrier amplifier, a first output terminal, and a second output terminal; and a second transformer including a first input terminal and a second input terminal, which are respectively connected to the first output terminal and the second output terminal of the first transformer, and an output terminal connected to a first antenna connection terminal, in which the first phase shift circuit is connected between the first output terminal of the first transformer and the first input terminal of the second transformer, and the first peak amplifier and the second phase shift circuit are connected between the second output terminal of the first transformer and the second input terminal of the second transformer.
<2> The Doherty amplification circuit according to <1>, in which the first transformer includes a first input side coil having the input terminal of the first transformer at one end, a second input side coil having one end connected to the other end of the first input side coil of the first transformer, a first output side coil having the first output terminal of the first transformer at one end and configured to couple with the first input side coil of the first transformer, and a second output side coil having the second output terminal of the first transformer at one end and configured to couple with the second input side coil of the first transformer, and the second transformer includes an input side coil having the first input terminal and the second input terminal of the second transformer at both ends, and an output side coil having the output terminal of the second transformer at one end and configured to couple with the input side coil of the second transformer.
<3> The Doherty amplification circuit according to <2>, further including: a second carrier amplifier; a second peak amplifier; a third phase shift circuit; a fourth phase shift circuit connected to an output end of the second peak amplifier; a third transformer including an input terminal connected to an output end of the second carrier amplifier, a first output terminal, and a second output terminal; and a fourth transformer including a first input terminal and a second input terminal, which are respectively connected to the first output terminal and the second output terminal of the third transformer, and an output terminal, in which the third phase shift circuit is connected between the first output terminal of the third transformer and the first input terminal of the fourth transformer, the second peak amplifier and the fourth phase shift circuit are connected between the second output terminal of the third transformer and the second input terminal of the fourth transformer, the third transformer includes a first input side coil having the input terminal of the third transformer at one end, a second input side coil having one end connected to the other end of the first input side coil of the third transformer, a first output side coil having the first output terminal of the third transformer at one end and configured to couple with the first input side coil of the third transformer, and a second output side coil having the second output terminal of the third transformer at one end and configured to couple with the second input side coil of the third transformer, the fourth transformer includes an input side coil having the first input terminal and the second input terminal of the fourth transformer at both ends, and an output side coil having the output terminal of the fourth transformer at one end and configured to couple with the input side coil of the fourth transformer, and the Doherty amplification circuit further includes a first switch connected between the other end of the output side coil of the second transformer and the output terminal of the fourth transformer, a second switch connected between the other end of the output side coil of the second transformer and a ground, and a third switch connected between the output terminal of the fourth transformer and a second antenna connection terminal.
<4> The Doherty amplification circuit according to <3>, in which, in a situation in which the Doherty amplification circuit is used in 2×2 multiple-input and multiple-output (MIMO), the first switch does not connect the other end of the output side coil of the second transformer to the output terminal of the fourth transformer, the second switch connects the other end of the output side coil of the second transformer to the ground, and the third switch connects the output terminal of the fourth transformer to the second antenna connection terminal.
<5> The Doherty amplification circuit according to <3> or <4>, in which, in a situation in which the Doherty amplification circuit is used in single-input and single-output (SISO), the first switch connects the other end of the output side coil of the second transformer to the output terminal of the fourth transformer, the second switch does not connect the other end of the output side coil of the second transformer to the ground, and the third switch does not connect the output terminal of the fourth transformer to the second antenna connection terminal.
<6> The Doherty amplification circuit according to any one of <3> to <5>, further including: a third carrier amplifier and a fourth carrier amplifier; a third peak amplifier and a fourth peak amplifier; a fifth phase shift circuit; a sixth phase shift circuit connected to an output end of the third peak amplifier; a seventh phase shift circuit; an eighth phase shift circuit connected to an output end of the fourth peak amplifier; a fifth transformer including an input terminal connected to an output end of the third carrier amplifier, a first output terminal, and a second output terminal; a sixth transformer including a first input terminal and a second input terminal, which are respectively connected to the first output terminal and the second output terminal of the fifth transformer, and an output terminal; a seventh transformer including an input terminal connected to an output end of the fourth carrier amplifier, a first output terminal, and a second output terminal; and an eighth transformer including a first input terminal and a second input terminal, which are respectively connected to the first output terminal and the second output terminal of the seventh transformer, and an output terminal, in which the fifth phase shift circuit is connected between the first output terminal of the fifth transformer and the first input terminal of the sixth transformer, the third peak amplifier and the sixth phase shift circuit are connected between the second output terminal of the fifth transformer and the second input terminal of the sixth transformer, the seventh phase shift circuit is connected between the first output terminal of the seventh transformer and the first input terminal of the eighth transformer, the fourth peak amplifier and the eighth phase shift circuit are connected between the second output terminal of the seventh transformer and the second input terminal of the eighth transformer, the fifth transformer includes a first input side coil having the input terminal of the fifth transformer at one end, a second input side coil having one end connected to the other end of the first input side coil of the fifth transformer, a first output side coil having the first output terminal of the fifth transformer at one end and configured to couple with the first input side coil of the fifth transformer, and a second output side coil having the second output terminal of the fifth transformer at one end and configured to couple with the second input side coil of the fifth transformer, the sixth transformer includes an input side coil having the first input terminal and the second input terminal of the sixth transformer at both ends, and an output side coil having the output terminal of the sixth transformer at one end and configured to couple with the input side coil of the sixth transformer, the seventh transformer includes a first input side coil having the input terminal of the seventh transformer at one end, a second input side coil having one end connected to the other end of the first input side coil of the seventh transformer, a first output side coil having the first output terminal of the seventh transformer at one end and configured to couple with the first input side coil of the seventh transformer, and a second output side coil having the second output terminal of the seventh transformer at one end and configured to couple with the second input side coil of the seventh transformer, the eighth transformer includes an input side coil having the first input terminal and the second input terminal of the eighth transformer at both ends, and an output side coil having the output terminal of the eighth transformer at one end and configured to couple with the input side coil of the eighth transformer, and the Doherty amplification circuit further includes a fourth switch connected between the other end of the output side coil of the fourth transformer and the output terminal of the sixth transformer, a fifth switch connected between the other end of the output side coil of the fourth transformer and the ground, a sixth switch connected between the output terminal of the sixth transformer and a third antenna connection terminal, a seventh switch connected between the other end of the output side coil of the sixth transformer and the output terminal of the eighth transformer, an eighth switch connected between the other end of the output side coil of the sixth transformer and the ground, and a ninth switch connected between the output terminal of the eighth transformer and a fourth antenna connection terminal.
<7> The Doherty amplification circuit according to <6>, in which, in a situation in which the Doherty amplification circuit is used in 4×4 MIMO, the first switch does not connect the other end of the output side coil of the second transformer to the output terminal of the fourth transformer, the second switch connects the other end of the output side coil of the second transformer to the ground, the third switch connects the output terminal of the fourth transformer to the second antenna connection terminal, the fourth switch does not connect the other end of the output side coil of the fourth transformer to the output terminal of the sixth transformer, the fifth switch connects the other end of the output side coil of the fourth transformer to the ground, the sixth switch connects the output terminal of the sixth transformer to the third antenna connection terminal, the seventh switch does not connect the other end of the output side coil of the sixth transformer to the output terminal of the eighth transformer, the eighth switch connects the other end of the output side coil of the sixth transformer to the ground, and the ninth switch connects the output terminal of the eighth transformer to the fourth antenna connection terminal.
<8> The Doherty amplification circuit according to <6> or <7>, in which, in a situation in which the Doherty amplification circuit is used in 2×2 MIMO, the first switch connects the other end of the output side coil of the second transformer to the output terminal of the fourth transformer, the second switch does not connect the other end of the output side coil of the second transformer to the ground, the third switch does not connect the output terminal of the fourth transformer to the second antenna connection terminal, the fourth switch does not connect the other end of the output side coil of the fourth transformer to the output terminal of the sixth transformer, the fifth switch connects the other end of the output side coil of the fourth transformer to the ground, the sixth switch connects the output terminal of the sixth transformer to the third antenna connection terminal, the seventh switch connects the other end of the output side coil of the sixth transformer to the output terminal of the eighth transformer, the eighth switch does not connect the other end of the output side coil of the sixth transformer to the ground, and the ninth switch does not connect the output terminal of the eighth transformer to the fourth antenna connection terminal.
<9> The Doherty amplification circuit according to any one of <6> to <8>, in which, in a situation in which the Doherty amplification circuit is used in SISO, the first switch connects the other end of the output side coil of the second transformer to the output terminal of the fourth transformer, the second switch does not connect the other end of the output side coil of the second transformer to the ground, the third switch does not connect the output terminal of the fourth transformer to the second antenna connection terminal, the fourth switch connects the other end of the output side coil of the fourth transformer to the output terminal of the sixth transformer, the fifth switch does not connect the other end of the output side coil of the fourth transformer to the ground, the sixth switch does not connect the output terminal of the sixth transformer to the third antenna connection terminal, the seventh switch connects the other end of the output side coil of the sixth transformer to the output terminal of the eighth transformer, the eighth switch does not connect the other end of the output side coil of the sixth transformer to the ground, and the ninth switch does not connect the output terminal of the eighth transformer to the fourth antenna connection terminal.
<10> The Doherty amplification circuit according to <2>, further including: a second peak amplifier; a third phase shift circuit; a fourth phase shift circuit connected to an output end of the second peak amplifier; a third transformer including an input terminal connected to the other end of the second input side coil of the first transformer, a first output terminal, and a second output terminal; and a fourth transformer including a first input terminal and a second input terminal, which are respectively connected to the first output terminal and the second output terminal of the third transformer, and an output terminal, in which the third phase shift circuit is connected between the first output terminal of the third transformer and the first input terminal of the fourth transformer, the second peak amplifier and the fourth phase shift circuit are connected between the second output terminal of the third transformer and the second input terminal of the fourth transformer, the third transformer includes a first input side coil having the input terminal of the third transformer at one end, a second input side coil having one end connected to the other end of the first input side coil of the third transformer, a first output side coil having the first output terminal of the third transformer at one end and configured to couple with the first input side coil of the third transformer, and a second output side coil having the second output terminal of the third transformer at one end and configured to couple with the second input side coil of the third transformer, the fourth transformer includes an input side coil having the first input terminal and the second input terminal of the fourth transformer at both ends, and an output side coil having the output terminal of the fourth transformer at one end and configured to couple with the input side coil of the fourth transformer, and the output terminal of the fourth transformer is connected to the other end of the output side coil of the second transformer.
<11> A Doherty amplification circuit including: a carrier amplifier; a first peak amplifier and a second peak amplifier; a first phase shift circuit and a second phase shift circuit; a third phase shift circuit connected to an output end of the second peak amplifier; a first transformer including an input terminal connected to an output end of the carrier amplifier, a first output terminal, and a second output terminal; a second transformer including an input terminal connected to the second output terminal of the first transformer, a first output terminal, and a second output terminal; and a third transformer including a first input terminal, a second input terminal, and a third input terminal, which are respectively connected to the first output terminal of the first transformer and the first output terminal and the second output terminal of the second transformer, and an output terminal connected to an antenna connection terminal, in which the first phase shift circuit is connected between the first output terminal of the first transformer and the first input terminal of the third transformer, the first peak amplifier is connected between the second output terminal of the first transformer and the input terminal of the second transformer, the second phase shift circuit is connected between the first output terminal of the second transformer and the second input terminal of the third transformer, and the second peak amplifier and the third phase shift circuit are connected between the second output terminal of the second transformer and the third input terminal of the third transformer.
<12> The Doherty amplification circuit according to <11>, in which the first transformer includes a first input side coil having the input terminal of the first transformer at one end, a second input side coil having one end connected to the other end of the first input side coil of the first transformer, a first output side coil having the first output terminal of the first transformer at one end and configured to couple with the first input side coil of the first transformer, and a second output side coil having the second output terminal of the first transformer at one end and configured to couple with the second input side coil of the first transformer, the second transformer includes a first input side coil having the input terminal of the second transformer at one end, a second input side coil having one end connected to the other end of the first input side coil of the second transformer, a first output side coil having the first output terminal of the second transformer at one end and configured to couple with the first input side coil of the second transformer, and a second output side coil having the second output terminal of the second transformer at one end and configured to couple with the second input side coil of the second transformer, and the third transformer includes a first input side coil having the first input terminal of the third transformer at one end, a second input side coil having the second input terminal and the third input terminal of the third transformer at both ends, a first output side coil having the output terminal of the third transformer at one end and configured to couple with the first input side coil of the third transformer, and a second output side coil having one end connected to the other end of the first output side coil of the third transformer and configured to couple with the second input side coil of the third transformer.
<13> A Doherty amplification circuit including: a carrier amplifier configured to amplify an input signal; a first transformer configured to split the input signal amplified by the carrier amplifier into a first split signal and a second split signal; a first phase shift circuit configured to adjust a phase of the first split signal; a peak amplifier configured to amplify the second split signal; a second phase shift circuit configured to adjust a phase of the second split signal amplified by the peak amplifier; and a second transformer configured to combine the first split signal having the phase adjusted by the first phase shift circuit and the second split signal having the phase adjusted by the second phase shift circuit.

### INDUSTRIAL APPLICABILITY

The present disclosure can be widely used in a communication device such as a cellular phone, as a Doherty amplification circuit disposed at a front end portion.

### REFERENCE SIGNS LIST

1, 1A, 1B, 1C Doherty amplification circuit
2a, 2b, 2c, 2d antenna
3 RFIC
5, 5A, 5B, 5C communication device
11, 12, 13, 14 carrier amplifier
21, 21C, 22, 22C, 23, 24 peak amplifier
31, 32, 32C, 33, 33C, 34, 35, 36, 37, 38 phase shift circuit
41, 42, 42C, 43, 43C, 44, 45, 46, 47, 48 transformer
51, 52, 53, 54, 55, 56, 57, 58, 59 switch
101, 102, 103, 104 antenna connection terminal
111, 112, 113, 114 high frequency input terminal
411, 421, 421C, 422, 431, 431C, 432C, 433C, 441, 442, 451, 461, 462, 471, 481, 482 input terminal
412, 413, 422C, 423, 423C, 432, 433, 434C, 443, 452, 453, 463, 472, 473, 483 output terminal
414, 415, 424, 424C, 425C, 434, 435, 435C, 436C, 444, 454, 455, 464, 474, 475, 484 input side coil
416, 417, 425, 426C, 427C, 436, 437, 437C, 438C, 445, 456, 457, 465, 476, 477, 485 output side coil

1. A Doherty amplification circuit comprising:
a first carrier amplifier;
a first peak amplifier;
a first phase shift circuit;
a second phase shift circuit connected to an output end of the first peak amplifier;
a first transformer including an input terminal connected to an output end of the first carrier amplifier, a first output terminal, and a second output terminal; and
a second transformer including a first input terminal and a second input terminal, which are respectively connected to the first output terminal and the second output terminal of the first transformer, and an output terminal connected to a first antenna connection terminal,
wherein the first phase shift circuit is connected between the first output terminal of the first transformer and the first input terminal of the second transformer, and
the first peak amplifier and the second phase shift circuit are connected between the second output terminal of the first transformer and the second input terminal of the second transformer.

2. The Doherty amplification circuit according to claim 1,
wherein the first transformer includes
a first input side coil having the input terminal of the first transformer at one end,
a second input side coil having one end connected to another end of the first input side coil of the first transformer,
a first output side coil having the first output terminal of the first transformer at one end and configured to couple with the first input side coil of the first transformer, and
a second output side coil having the second output terminal of the first transformer at one end and configured to couple with the second input side coil of the first transformer, and
the second transformer includes
an input side coil having the first input terminal and the second input terminal of the second transformer at both ends, and
an output side coil having the output terminal of the second transformer at one end and configured to couple with the input side coil of the second transformer.

3. The Doherty amplification circuit according to claim 2, further comprising:
a second carrier amplifier;
a second peak amplifier;
a third phase shift circuit;
a fourth phase shift circuit connected to an output end of the second peak amplifier;
a third transformer including an input terminal connected to an output end of the second carrier amplifier, a first output terminal, and a second output terminal; and
a fourth transformer including a first input terminal and a second input terminal, which are respectively connected to the first output terminal and the second output terminal of the third transformer, and an output terminal,
wherein the third phase shift circuit is connected between the first output terminal of the third transformer and the first input terminal of the fourth transformer,
the second peak amplifier and the fourth phase shift circuit are connected between the second output terminal of the third transformer and the second input terminal of the fourth transformer,
the third transformer includes
a first input side coil having the input terminal of the third transformer at one end,
a second input side coil having one end connected to another end of the first input side coil of the third transformer,
a first output side coil having the first output terminal of the third transformer at one end and configured to couple with the first input side coil of the third transformer, and
a second output side coil having the second output terminal of the third transformer at one end and configured to couple with the second input side coil of the third transformer,
the fourth transformer includes
an input side coil having the first input terminal and the second input terminal of the fourth transformer at both ends, and
an output side coil having the output terminal of the fourth transformer at one end and configured to couple with the input side coil of the fourth transformer, and
the Doherty amplification circuit further includes
a first switch connected between another end of the output side coil of the second transformer and the output terminal of the fourth transformer,
a second switch connected between the other end of the output side coil of the second transformer and a ground, and
a third switch connected between the output terminal of the fourth transformer and a second antenna connection terminal.

4. The Doherty amplification circuit according to claim 3,
wherein, in a situation in which the Doherty amplification circuit is used in 2×2 multiple-input and multiple-output (MIMO),
the first switch does not connect the other end of the output side coil of the second transformer to the output terminal of the fourth transformer,
the second switch connects the other end of the output side coil of the second transformer to the ground, and
the third switch connects the output terminal of the fourth transformer to the second antenna connection terminal.

5. The Doherty amplification circuit according to claim 4,
wherein, in a situation in which the Doherty amplification circuit is used in single-input and single-output (SISO),
the first switch connects the other end of the output side coil of the second transformer to the output terminal of the fourth transformer,
the second switch does not connect the other end of the output side coil of the second transformer to the ground, and
the third switch does not connect the output terminal of the fourth transformer to the second antenna connection terminal.

6. The Doherty amplification circuit according to claim 5, further comprising:
a third carrier amplifier and a fourth carrier amplifier;
a third peak amplifier and a fourth peak amplifier;
a fifth phase shift circuit;
a sixth phase shift circuit connected to an output end of the third peak amplifier;
a seventh phase shift circuit;
an eighth phase shift circuit connected to an output end of the fourth peak amplifier;
a fifth transformer including an input terminal connected to an output end of the third carrier amplifier, a first output terminal, and a second output terminal;
a sixth transformer including a first input terminal and a second input terminal, which are respectively connected to the first output terminal and the second output terminal of the fifth transformer, and an output terminal;
a seventh transformer including an input terminal connected to an output end of the fourth carrier amplifier, a first output terminal, and a second output terminal; and
an eighth transformer including a first input terminal and a second input terminal, which are respectively connected to the first output terminal and the second output terminal of the seventh transformer, and an output terminal,
wherein the fifth phase shift circuit is connected between the first output terminal of the fifth transformer and the first input terminal of the sixth transformer,
the third peak amplifier and the sixth phase shift circuit are connected between the second output terminal of the fifth transformer and the second input terminal of the sixth transformer,
the seventh phase shift circuit is connected between the first output terminal of the seventh transformer and the first input terminal of the eighth transformer,
the fourth peak amplifier and the eighth phase shift circuit are connected between the second output terminal of the seventh transformer and the second input terminal of the eighth transformer,
the fifth transformer includes
a first input side coil having the input terminal of the fifth transformer at one end,
a second input side coil having one end connected to another end of the first input side coil of the fifth transformer,
a first output side coil having the first output terminal of the fifth transformer at one end and configured to couple with the first input side coil of the fifth transformer, and
a second output side coil having the second output terminal of the fifth transformer at one end and configured to couple with the second input side coil of the fifth transformer,
the sixth transformer includes
an input side coil having the first input terminal and the second input terminal of the sixth transformer at both ends, and
an output side coil having the output terminal of the sixth transformer at one end and configured to couple with the input side coil of the sixth transformer,
the seventh transformer includes
a first input side coil having the input terminal of the seventh transformer at one end,
a second input side coil having one end connected to another end of the first input side coil of the seventh transformer,
a first output side coil having the first output terminal of the seventh transformer at one end and configured to couple with the first input side coil of the seventh transformer, and
a second output side coil having the second output terminal of the seventh transformer at one end and configured to couple with the second input side coil of the seventh transformer,
the eighth transformer includes
an input side coil having the first input terminal and the second input terminal of the eighth transformer at both ends, and
an output side coil having the output terminal of the eighth transformer at one end and configured to couple with the input side coil of the eighth transformer, and
the Doherty amplification circuit further includes
a fourth switch connected between another end of the output side coil of the fourth transformer and the output terminal of the sixth transformer,
a fifth switch connected between the other end of the output side coil of the fourth transformer and the ground,
a sixth switch connected between the output terminal of the sixth transformer and a third antenna connection terminal,
a seventh switch connected between another end of the output side coil of the sixth transformer and the output terminal of the eighth transformer,
an eighth switch connected between the other end of the output side coil of the sixth transformer and the ground, and
a ninth switch connected between the output terminal of the eighth transformer and a fourth antenna connection terminal.

7. The Doherty amplification circuit according to claim 6,
wherein, in a situation in which the Doherty amplification circuit is used in 4×4 MIMO,
the first switch does not connect the other end of the output side coil of the second transformer to the output terminal of the fourth transformer,
the second switch connects the other end of the output side coil of the second transformer to the ground,
the third switch connects the output terminal of the fourth transformer to the second antenna connection terminal,
the fourth switch does not connect the other end of the output side coil of the fourth transformer to the output terminal of the sixth transformer,
the fifth switch connects the other end of the output side coil of the fourth transformer to the ground,
the sixth switch connects the output terminal of the sixth transformer to the third antenna connection terminal,
the seventh switch does not connect the other end of the output side coil of the sixth transformer to the output terminal of the eighth transformer,
the eighth switch connects the other end of the output side coil of the sixth transformer to the ground, and
the ninth switch connects the output terminal of the eighth transformer to the fourth antenna connection terminal.

8. The Doherty amplification circuit according to claim 7,
wherein, in a situation in which the Doherty amplification circuit is used in 2×2 MIMO,
the first switch connects the other end of the output side coil of the second transformer to the output terminal of the fourth transformer,
the second switch does not connect the other end of the output side coil of the second transformer to the ground,
the third switch does not connect the output terminal of the fourth transformer to the second antenna connection terminal,
the fourth switch does not connect the other end of the output side coil of the fourth transformer to the output terminal of the sixth transformer,
the fifth switch connects the other end of the output side coil of the fourth transformer to the ground,
the sixth switch connects the output terminal of the sixth transformer to the third antenna connection terminal,
the seventh switch connects the other end of the output side coil of the sixth transformer to the output terminal of the eighth transformer,
the eighth switch does not connect the other end of the output side coil of the sixth transformer to the ground, and
the ninth switch does not connect the output terminal of the eighth transformer to the fourth antenna connection terminal.

9. The Doherty amplification circuit according to claim 8,
wherein, in a situation in which the Doherty amplification circuit is used in SISO,
the first switch connects the other end of the output side coil of the second transformer to the output terminal of the fourth transformer,
the second switch does not connect the other end of the output side coil of the second transformer to the ground,
the third switch does not connect the output terminal of the fourth transformer to the second antenna connection terminal,
the fourth switch connects the other end of the output side coil of the fourth transformer to the output terminal of the sixth transformer,
the fifth switch does not connect the other end of the output side coil of the fourth transformer to the ground,
the sixth switch does not connect the output terminal of the sixth transformer to the third antenna connection terminal,
the seventh switch connects the other end of the output side coil of the sixth transformer to the output terminal of the eighth transformer,
the eighth switch does not connect the other end of the output side coil of the sixth transformer to the ground, and
the ninth switch does not connect the output terminal of the eighth transformer to the fourth antenna connection terminal.

10. The Doherty amplification circuit according to claim 2, further comprising:
a second peak amplifier;
a third phase shift circuit;
a fourth phase shift circuit connected to an output end of the second peak amplifier;
a third transformer including an input terminal connected to another end of the second input side coil of the first transformer, a first output terminal, and a second output terminal; and
a fourth transformer including a first input terminal and a second input terminal, which are respectively connected to the first output terminal and the second output terminal of the third transformer, and an output terminal,
wherein the third phase shift circuit is connected between the first output terminal of the third transformer and the first input terminal of the fourth transformer,
the second peak amplifier and the fourth phase shift circuit are connected between the second output terminal of the third transformer and the second input terminal of the fourth transformer,
the third transformer includes
a first input side coil having the input terminal of the third transformer at one end,
a second input side coil having one end connected to another end of the first input side coil of the third transformer,
a first output side coil having the first output terminal of the third transformer at one end and configured to couple with the first input side coil of the third transformer, and
a second output side coil having the second output terminal of the third transformer at one end and configured to couple with the second input side coil of the third transformer,
the fourth transformer includes
an input side coil having the first input terminal and the second input terminal of the fourth transformer at both ends, and
an output side coil having the output terminal of the fourth transformer at one end and configured to couple with the input side coil of the fourth transformer, and
the output terminal of the fourth transformer is connected to another end of the output side coil of the second transformer.

11. A Doherty amplification circuit comprising:
a carrier amplifier;
a first peak amplifier and a second peak amplifier;
a first phase shift circuit and a second phase shift circuit;
a third phase shift circuit connected to an output end of the second peak amplifier;
a first transformer including an input terminal connected to an output end of the carrier amplifier, a first output terminal, and a second output terminal;
a second transformer including an input terminal connected to the second output terminal of the first transformer, a first output terminal, and a second output terminal; and
a third transformer including a first input terminal, a second input terminal, and a third input terminal, which are respectively connected to the first output terminal of the first transformer and the first output terminal and the second output terminal of the second transformer, and an output terminal connected to an antenna connection terminal,
wherein the first phase shift circuit is connected between the first output terminal of the first transformer and the first input terminal of the third transformer,
the first peak amplifier is connected between the second output terminal of the first transformer and the input terminal of the second transformer,
the second phase shift circuit is connected between the first output terminal of the second transformer and the second input terminal of the third transformer, and
the second peak amplifier and the third phase shift circuit are connected between the second output terminal of the second transformer and the third input terminal of the third transformer.

12. The Doherty amplification circuit according to claim 11,
wherein the first transformer includes
a first input side coil having the input terminal of the first transformer at one end,
a second input side coil having one end connected to another end of the first input side coil of the first transformer,
a first output side coil having the first output terminal of the first transformer at one end and configured to couple with the first input side coil of the first transformer, and
a second output side coil having the second output terminal of the first transformer at one end and configured to couple with the second input side coil of the first transformer,
the second transformer includes
a first input side coil having the input terminal of the second transformer at one end,
a second input side coil having one end connected to another end of the first input side coil of the second transformer,
a first output side coil having the first output terminal of the second transformer at one end and configured to couple with the first input side coil of the second transformer, and
a second output side coil having the second output terminal of the second transformer at one end and configured to couple with the second input side coil of the second transformer, and
the third transformer includes
a first input side coil having the first input terminal of the third transformer at one end,
a second input side coil having the second input terminal and the third input terminal of the third transformer at both ends,
a first output side coil having the output terminal of the third transformer at one end and configured to couple with the first input side coil of the third transformer, and
a second output side coil having one end connected to another end of the first output side coil of the third transformer and configured to couple with the second input side coil of the third transformer.

13. A Doherty amplification circuit comprising:
a carrier amplifier configured to amplify an input signal;
a first transformer configured to split the input signal amplified by the carrier amplifier into a first split signal and a second split signal;
a first phase shift circuit configured to adjust a phase of the first split signal;
a peak amplifier configured to amplify the second split signal;
a second phase shift circuit configured to adjust a phase of the second split signal amplified by the peak amplifier; and
a second transformer configured to combine the first split signal having the phase adjusted by the first phase shift circuit and the second split signal having the phase adjusted by the second phase shift circuit.

14. The Doherty amplification circuit according to claim 3,
wherein, in a situation in which the Doherty amplification circuit is used in single-input and single-output (SISO),
the first switch connects the other end of the output side coil of the second transformer to the output terminal of the fourth transformer,
the second switch does not connect the other end of the output side coil of the second transformer to the ground, and
the third switch does not connect the output terminal of the fourth transformer to the second antenna connection terminal.

15. The Doherty amplification circuit according to claim 14, further comprising:
a third carrier amplifier and a fourth carrier amplifier;
a third peak amplifier and a fourth peak amplifier;
a fifth phase shift circuit;
a sixth phase shift circuit connected to an output end of the third peak amplifier;
a seventh phase shift circuit;
an eighth phase shift circuit connected to an output end of the fourth peak amplifier;
a fifth transformer including an input terminal connected to an output end of the third carrier amplifier, a first output terminal, and a second output terminal;
a sixth transformer including a first input terminal and a second input terminal, which are respectively connected to the first output terminal and the second output terminal of the fifth transformer, and an output terminal;
a seventh transformer including an input terminal connected to an output end of the fourth carrier amplifier, a first output terminal, and a second output terminal; and
an eighth transformer including a first input terminal and a second input terminal, which are respectively connected to the first output terminal and the second output terminal of the seventh transformer, and an output terminal,
wherein the fifth phase shift circuit is connected between the first output terminal of the fifth transformer and the first input terminal of the sixth transformer,
the third peak amplifier and the sixth phase shift circuit are connected between the second output terminal of the fifth transformer and the second input terminal of the sixth transformer,
the seventh phase shift circuit is connected between the first output terminal of the seventh transformer and the first input terminal of the eighth transformer,
the fourth peak amplifier and the eighth phase shift circuit are connected between the second output terminal of the seventh transformer and the second input terminal of the eighth transformer,
the fifth transformer includes
a first input side coil having the input terminal of the fifth transformer at one end,
a second input side coil having one end connected to another end of the first input side coil of the fifth transformer,
a first output side coil having the first output terminal of the fifth transformer at one end and configured to couple with the first input side coil of the fifth transformer, and
a second output side coil having the second output terminal of the fifth transformer at one end and configured to couple with the second input side coil of the fifth transformer,
the sixth transformer includes
an input side coil having the first input terminal and the second input terminal of the sixth transformer at both ends, and
an output side coil having the output terminal of the sixth transformer at one end and configured to couple with the input side coil of the sixth transformer,
the seventh transformer includes
a first input side coil having the input terminal of the seventh transformer at one end,
a second input side coil having one end connected to another end of the first input side coil of the seventh transformer,
a first output side coil having the first output terminal of the seventh transformer at one end and configured to couple with the first input side coil of the seventh transformer, and
a second output side coil having the second output terminal of the seventh transformer at one end and configured to couple with the second input side coil of the seventh transformer,
the eighth transformer includes
an input side coil having the first input terminal and the second input terminal of the eighth transformer at both ends, and
an output side coil having the output terminal of the eighth transformer at one end and configured to couple with the input side coil of the eighth transformer, and
the Doherty amplification circuit further includes
a fourth switch connected between another end of the output side coil of the fourth transformer and the output terminal of the sixth transformer,
a fifth switch connected between the other end of the output side coil of the fourth transformer and the ground,
a sixth switch connected between the output terminal of the sixth transformer and a third antenna connection terminal,
a seventh switch connected between another end of the output side coil of the sixth transformer and the output terminal of the eighth transformer,
an eighth switch connected between the other end of the output side coil of the sixth transformer and the ground, and
a ninth switch connected between the output terminal of the eighth transformer and a fourth antenna connection terminal.

16. The Doherty amplification circuit according to claim 3, further comprising:
a third carrier amplifier and a fourth carrier amplifier;
a third peak amplifier and a fourth peak amplifier;
a fifth phase shift circuit;
a sixth phase shift circuit connected to an output end of the third peak amplifier;
a seventh phase shift circuit;
an eighth phase shift circuit connected to an output end of the fourth peak amplifier;
a fifth transformer including an input terminal connected to an output end of the third carrier amplifier, a first output terminal, and a second output terminal;
a sixth transformer including a first input terminal and a second input terminal, which are respectively connected to the first output terminal and the second output terminal of the fifth transformer, and an output terminal;
a seventh transformer including an input terminal connected to an output end of the fourth carrier amplifier, a first output terminal, and a second output terminal; and
an eighth transformer including a first input terminal and a second input terminal, which are respectively connected to the first output terminal and the second output terminal of the seventh transformer, and an output terminal,
wherein the fifth phase shift circuit is connected between the first output terminal of the fifth transformer and the first input terminal of the sixth transformer,
the third peak amplifier and the sixth phase shift circuit are connected between the second output terminal of the fifth transformer and the second input terminal of the sixth transformer,
the seventh phase shift circuit is connected between the first output terminal of the seventh transformer and the first input terminal of the eighth transformer,
the fourth peak amplifier and the eighth phase shift circuit are connected between the second output terminal of the seventh transformer and the second input terminal of the eighth transformer,
the fifth transformer includes
a first input side coil having the input terminal of the fifth transformer at one end,
a second input side coil having one end connected to another end of the first input side coil of the fifth transformer,
a first output side coil having the first output terminal of the fifth transformer at one end and configured to couple with the first input side coil of the fifth transformer, and
a second output side coil having the second output terminal of the fifth transformer at one end and configured to couple with the second input side coil of the fifth transformer,
the sixth transformer includes
an input side coil having the first input terminal and the second input terminal of the sixth transformer at both ends, and
an output side coil having the output terminal of the sixth transformer at one end and configured to couple with the input side coil of the sixth transformer,
the seventh transformer includes
a first input side coil having the input terminal of the seventh transformer at one end,
a second input side coil having one end connected to another end of the first input side coil of the seventh transformer,
a first output side coil having the first output terminal of the seventh transformer at one end and configured to couple with the first input side coil of the seventh transformer, and
a second output side coil having the second output terminal of the seventh transformer at one end and configured to couple with the second input side coil of the seventh transformer,
the eighth transformer includes
an input side coil having the first input terminal and the second input terminal of the eighth transformer at both ends, and
an output side coil having the output terminal of the eighth transformer at one end and configured to couple with the input side coil of the eighth transformer, and
the Doherty amplification circuit further includes
a fourth switch connected between another end of the output side coil of the fourth transformer and the output terminal of the sixth transformer,
a fifth switch connected between the other end of the output side coil of the fourth transformer and the ground,
a sixth switch connected between the output terminal of the sixth transformer and a third antenna connection terminal,
a seventh switch connected between another end of the output side coil of the sixth transformer and the output terminal of the eighth transformer,
an eighth switch connected between the other end of the output side coil of the sixth transformer and the ground, and
a ninth switch connected between the output terminal of the eighth transformer and a fourth antenna connection terminal.

17. The Doherty amplification circuit according to claim 4, further comprising:
a third carrier amplifier and a fourth carrier amplifier;
a third peak amplifier and a fourth peak amplifier;
a fifth phase shift circuit;
a sixth phase shift circuit connected to an output end of the third peak amplifier;
a seventh phase shift circuit;
an eighth phase shift circuit connected to an output end of the fourth peak amplifier;
a fifth transformer including an input terminal connected to an output end of the third carrier amplifier, a first output terminal, and a second output terminal;
a sixth transformer including a first input terminal and a second input terminal, which are respectively connected to the first output terminal and the second output terminal of the fifth transformer, and an output terminal;
a seventh transformer including an input terminal connected to an output end of the fourth carrier amplifier, a first output terminal, and a second output terminal; and
an eighth transformer including a first input terminal and a second input terminal, which are respectively connected to the first output terminal and the second output terminal of the seventh transformer, and an output terminal,
wherein the fifth phase shift circuit is connected between the first output terminal of the fifth transformer and the first input terminal of the sixth transformer,
the third peak amplifier and the sixth phase shift circuit are connected between the second output terminal of the fifth transformer and the second input terminal of the sixth transformer,
the seventh phase shift circuit is connected between the first output terminal of the seventh transformer and the first input terminal of the eighth transformer,
the fourth peak amplifier and the eighth phase shift circuit are connected between the second output terminal of the seventh transformer and the second input terminal of the eighth transformer,
the fifth transformer includes
a first input side coil having the input terminal of the fifth transformer at one end,
a second input side coil having one end connected to another end of the first input side coil of the fifth transformer,
a first output side coil having the first output terminal of the fifth transformer at one end and configured to couple with the first input side coil of the fifth transformer, and
a second output side coil having the second output terminal of the fifth transformer at one end and configured to couple with the second input side coil of the fifth transformer,
the sixth transformer includes
an input side coil having the first input terminal and the second input terminal of the sixth transformer at both ends, and
an output side coil having the output terminal of the sixth transformer at one end and configured to couple with the input side coil of the sixth transformer,
the seventh transformer includes
a first input side coil having the input terminal of the seventh transformer at one end,
a second input side coil having one end connected to another end of the first input side coil of the seventh transformer,
a first output side coil having the first output terminal of the seventh transformer at one end and configured to couple with the first input side coil of the seventh transformer, and
a second output side coil having the second output terminal of the seventh transformer at one end and configured to couple with the second input side coil of the seventh transformer,
the eighth transformer includes
an input side coil having the first input terminal and the second input terminal of the eighth transformer at both ends, and
an output side coil having the output terminal of the eighth transformer at one end and configured to couple with the input side coil of the eighth transformer, and
the Doherty amplification circuit further includes
a fourth switch connected between another end of the output side coil of the fourth transformer and the output terminal of the sixth transformer,
a fifth switch connected between the other end of the output side coil of the fourth transformer and the ground,
a sixth switch connected between the output terminal of the sixth transformer and a third antenna connection terminal,
a seventh switch connected between another end of the output side coil of the sixth transformer and the output terminal of the eighth transformer,
an eighth switch connected between the other end of the output side coil of the sixth transformer and the ground, and
a ninth switch connected between the output terminal of the eighth transformer and a fourth antenna connection terminal.

18. The Doherty amplification circuit according to claim 6,
wherein, in a situation in which the Doherty amplification circuit is used in 2×2 MIMO,
the first switch connects the other end of the output side coil of the second transformer to the output terminal of the fourth transformer,
the second switch does not connect the other end of the output side coil of the second transformer to the ground,
the third switch does not connect the output terminal of the fourth transformer to the second antenna connection terminal,
the fourth switch does not connect the other end of the output side coil of the fourth transformer to the output terminal of the sixth transformer,
the fifth switch connects the other end of the output side coil of the fourth transformer to the ground,
the sixth switch connects the output terminal of the sixth transformer to the third antenna connection terminal,
the seventh switch connects the other end of the output side coil of the sixth transformer to the output terminal of the eighth transformer,
the eighth switch does not connect the other end of the output side coil of the sixth transformer to the ground, and
the ninth switch does not connect the output terminal of the eighth transformer to the fourth antenna connection terminal.

19. The Doherty amplification circuit according to claim 6,
wherein, in a situation in which the Doherty amplification circuit is used in SISO,
the first switch connects the other end of the output side coil of the second transformer to the output terminal of the fourth transformer,
the second switch does not connect the other end of the output side coil of the second transformer to the ground,
the third switch does not connect the output terminal of the fourth transformer to the second antenna connection terminal,
the fourth switch connects the other end of the output side coil of the fourth transformer to the output terminal of the sixth transformer,
the fifth switch does not connect the other end of the output side coil of the fourth transformer to the ground,
the sixth switch does not connect the output terminal of the sixth transformer to the third antenna connection terminal,
the seventh switch connects the other end of the output side coil of the sixth transformer to the output terminal of the eighth transformer,
the eighth switch does not connect the other end of the output side coil of the sixth transformer to the ground, and
the ninth switch does not connect the output terminal of the eighth transformer to the fourth antenna connection terminal.

20. The Doherty amplification circuit according to claim 7,
wherein, in a situation in which the Doherty amplification circuit is used in SISO,
the first switch connects the other end of the output side coil of the second transformer to the output terminal of the fourth transformer,
the second switch does not connect the other end of the output side coil of the second transformer to the ground,
the third switch does not connect the output terminal of the fourth transformer to the second antenna connection terminal,
the fourth switch connects the other end of the output side coil of the fourth transformer to the output terminal of the sixth transformer,
the fifth switch does not connect the other end of the output side coil of the fourth transformer to the ground,
the sixth switch does not connect the output terminal of the sixth transformer to the third antenna connection terminal,
the seventh switch connects the other end of the output side coil of the sixth transformer to the output terminal of the eighth transformer,
the eighth switch does not connect the other end of the output side coil of the sixth transformer to the ground, and
the ninth switch does not connect the output terminal of the eighth transformer to the fourth antenna connection terminal.
